(19) United States
(12) Patent Application Publication
(10) Pub. No.: US 2018/0323076 A1
(43) Pub. Date: Nov. 8, 2018

(54) Substrate Processing Method and Solvent Used for Same Method

(71) Applicant: Central Glass Company, Limited, Ube-shi,Yamaguchi (JP)

(72) Inventors: Akifumi YAO, Ube-shi, Yamaguchi (JP); Soichi KUMON, Matsusaka-shi, Mie (JP); Masaki FUJIWARA, Chiyoda-ku, Tokyo (JP); Hidehisa NANAI, Toshima-ku, Tokyo (JP)

(73) Assignee: Central Glass Company ,Limited, Ube-shi ,Yamaguchi (JP)

(21) Appl. No.: 15/773,834

(22) PCT Filed: Oct. 26, 2016
(86) PCT No.: PCT/JP2016/081718

§ 371 Date: May 4, 2018

(30) Foreign Application Priority Data
Nov. 11, 2015 (JP) 2015-221592

(51) Int. Cl. H01L 21/311; H01L 21/67; B08B 3/08; B08B 3/10; C11D 7/26; C11D 7/02; C11D 7/50

(52) U.S. Cl. CPC H01L 21/31133; H01L 21/6708; B08B 3/08; C11D 7/5018; C11D 7/261; C11D 7/02; B08B 3/10

(57) ABSTRACT

A processing method of a semiconductor substrate according the present invention includes: cleaning a surface of the semiconductor substrate with a water-based cleaning liquid; and drying the semiconductor substrate by replacing the water-based cleaning liquid attached to the surface of the semiconductor substrate with a supercritical fluid, characterized by using as the supercritical fluid a C₂-C₆ fluoroalcohol-containing solvent whose Fe, Ni, Cr, Al, Zn, Cu, Mg, Li, K, Na and Ca contents are each 500 mass ppb or less. In this processing method, it is possible to reduce the amount of fluorine atoms released in the supercritical fluid.

### FIELD OF THE INVENTION

The present invention relates to a substrate processing method and a solvent for use in the substrate processing method.

### BACKGROUND ART

Semiconductor devices for network applications and digital home appliances are required to achieve higher performance, higher functionality and lower power consumption. For this purpose, the fine processing of circuit patterns has been pursued. With the fine processing of the circuit patterns, however, pattern collapses are becoming a problem. The manufacturing of the semiconductor device makes heavy use of cleaning process to remove particles and metal impurities so that the cleaning process occupies 30 to 40% of the entire semiconductor manufacturing process. The pattern collapse is a phenomenon occurring in the cleaning process when the aspect ratio of hole or recess portions of the uneven pattern becomes high. More specifically, the pattern collapse refers to a collapse of the pattern caused due to the passage of a gas-liquid interface through the pattern after cleaning or rinsing. The design of the pattern has to be changed in order to prevent the pattern collapse. Further, the occurrence of the pattern collapse leads to a deterioration in manufacturing yield. It is thus demanded to develop a method for preventing the pattern collapse in the cleaning process.

As a technique to solve the above problem, there is known a cleaning and method of cleaning and drying a substrate by treating the substrate with a supercritical fluid of substantially zero surface tension, and then, gasifying the supercritical fluid without going through a liquid state (see, for example, Patent Documents 1 and 2).

In particular, Patent Document 1 discloses a method for cleaning a device substrate, including a cleaning step of cleaning off a resist adhered to the device substrate with a solvent so as to sufficiently remove the resist adhered to the device substrate, especially the resist adhered to hole portions of the high-aspect-ratio fine pattern of the device substrate, wherein the solvent is a composition containing at least one kind of fluorine-containing compound selected from the group consisting of hydrofluoroethers hydrofluorocarbons and perfluorocarbons and a fluoroalcohol. Patent Document 1 also discloses that the cleaning step is performed using the solvent in liquid form and then using the solvent in supercritical fluid form.

### PRIOR ART DOCUMENTS

### Patent Documents

Patent Document 1: International Publication No. 2007/114448

Patent Document 2: Japanese Patent No. 5506461

### SUMMARY OF THE INVENTION

### Problems to be Solved by the Invention

The cleaning method of Patent Document 1, which uses the supercritical fluid of low surface tension and high diffusion coefficient, makes it possible to remove the resist from between pattern portions by easy penetration of the supercritical fluid into fine spaces. As a result of researches made by the present inventors, however, it has been found that when the fluorine-based solvent (such as fluoroalcohol) used as the supercritical fluid in this cleaning method contains a large amount of metal impurities, fluorine atoms are likely to be released from the fluorine-based solvent, in the form of hydrogen fluoride (HF) or metal fluoride, by change of the fluorine-based solvent to the supercritical fluid. Although the detailed mechanism of such fluorine atom release is not clear, it is assumed that the fluorine atoms are released due to thermal decomposition of the fluorine-based solvent under a high-temperature high-pressure supercritical state. In the case of processing the substrate having on its surface a SiO₂ film as in Patent Document 2, the fluorine atoms released from the fluorine-based solvent may cause etching of the SiO₂ film. Further, the released fluorine atoms may be embedded in the semiconductor device such as substrate or pattern and thereby become a cause of deterioration in device performance.

In view of the foregoing, it is an object of the present invention to provide a substrate processing method using a supercritical fluid in which the amount of fluorine atoms released is reduced and to provide a solvent for use in the substrate processing method.

### Means for Solving the Problems

The present invention provides a processing method of a semiconductor substrate, comprising: cleaning a surface of the semiconductor substrate with a water-based cleaning liquid; and drying the semiconductor substrate by replacing the cleaning liquid adhered to the surface of the semiconductor substrate with a supercritical fluid, wherein the supercritical fluid is of a C₂-C₆ fluoroalcohol-containing solvent whose Fe, Ni, Cr, Al, Zn, Cu, Mg, Li, K, Na and Ca contents are each 500 mass ppb or less.

According to a preferred embodiment (hereinafter referred to as “first embodiment”) of the present invention, the processing method of the semiconductor substrate is carried out through the following steps:
(1-1) supplying the water-based cleaning liquid to the surface of the semiconductor substrate;
(1-2) supplying the C₂-C₆ fluoroalcohol-containing solvent whose Fe, Ni, Cr, Al, Zn, Cu, Mg, Li, K, Na and Ca contents are each 500 mass ppb or less (also simply referred to as “fluoroalcohol-containing solvent”) to the surface of the semiconductor substrate to which the water-based cleaning liquid has been attached;
(1-3) moving the semiconductor substrate to which the fluoroalcohol-containing solvent has been attached into a chamber, and then, controlling temperature and pressure inside the chamber to be higher than or equal to a critical point of the fluoroalcohol-containing solvent to thereby change the fluoroalcohol-containing solvent to the supercritical fluid;
(1-4) changing the supercritical fluid to a gas by lowering the pressure inside the chamber; and
(1-5) taking the semiconductor substrate out of the chamber.

In the first embodiment, the C₂-C₆ fluoroalcohol-containing solvent whose Fe, Ni, Cr, Al, Zn, Cu, Mg, Li, K, Na and Ca contents are each 500 mass ppb or less (fluoroalcohol-containing solvent) is preferably supplied to replace the water-based cleaning liquid attached to the surface of the substrate in the step (1-2). Such replacement leads to easy change of the fluoroalcohol-containing solvent to the supercritical fluid in the subsequent step (1-3).

In the first embodiment, the fluoroalcohol-containing solvent is preferably a C₂-C₆ fluoroalcohol.

In the first embodiment, the purity of the C₂-C₆ fluoroalcohol is preferably 99.5% or higher.

In the first embodiment, the C₂-C₆ fluoroalcohol is preferably at least one selected from the group consisting of CH₂CHCH₂C(CF₃)₂OH, CHF₂CF₂CH₂OH, (CF₃)₃COH, CH₃(CF₃)₂COH, CF₃CH(OH)CF₃ and CF₃CH₂OH.

In the first embodiment, the water content of the water-based cleaning liquid is preferably 80 mass % or more.

In the first embodiment, the water-based cleaning liquid is preferably water.

According to another preferred embodiment (hereinafter referred to as “second embodiment”) of the present invention, the processing method of the semiconductor substrate is carried out through the following steps:
(2-1) supplying the water-based cleaning liquid to the surface of the semiconductor substrate;
(2-2) supplying the C₂-C₆ fluoroalcohol-containing solvent whose Fe, Ni, Cr, Al, Zn, Cu, Mg, Li, K, Na and Ca contents are 500 mass ppb or less (also simply referred to as “fluoroalcohol-containing solvent”) to the surface of the semiconductor substrate to which the water-based cleaning liquid has been attached;
(2-3) moving the semiconductor substrate to which the fluoroalcohol-containing solvent has been attached into a chamber, and then, replacing the fluoroalcohol-containing solvent attached to the semiconductor substrate with the supercritical fluid of the fluoroalcohol-containing solvent, wherein the supercritical fluid has been separately obtained by controlling temperature and pressure of the fluoroalcohol-containing solvent to be higher than or equal to a critical point of the fluoroalcohol-containing solvent;
(2-4) changing the supercritical fluid to a gas by lowering the pressure inside the chamber; and
(2-5) taking the semiconductor substrate out of the chamber.

In the second embodiment, the C₂-C₆ fluoroalcohol-containing solvent whose Fe, Ni, Cr, Al, Zn, Cu, Mg, Li, K, Na and Ca contents are each 500 mass ppb or less (fluoroalcohol-containing solvent) is preferably supplied to replace the water-based cleaning liquid attached to the surface of the substrate in the step (2-2). Such replacement leads to easy replacement of the fluoroalcohol-containing solvent with the supercritical fluid in the subsequent step (2-3).

In the second embodiment, the fluoroalcohol-containing solvent is preferably a C₂-C₆ fluoroalcohol.

In the second embodiment, the purity of the C₂-C₆ fluoroalcohol is preferably 99.5% or higher.

In the second embodiment, the C₂-C₆ fluoroalcohol is preferably at least one selected from the group consisting of CH₂CHCH₂C(CF₃)₂OH, CHF₂CF₂CH₂OH, (CF₃)₃COH, CH₃(CF₃)₂COH, CF₃CH(OH)CF₃ and CF₃CH₂OH.

In the second embodiment, the water content of the water-based cleaning liquid is preferably 80 mass % or more.

In the second embodiment, the water-based cleaning liquid is preferably water.

According to another preferred embodiment (hereinafter referred to as “third embodiment”) of the present invention, the processing method of the semiconductor substrate is carried out through the following steps:
(3-1) supplying the water-based cleaning liquid to the surface of the semiconductor substrate;
(3-2) moving the semiconductor substrate to which the water-based cleaning liquid has been attached into a chamber, and then, replacing the water-based cleaning liquid attached to the semiconductor substrate with the supercritical fluid of the C₂-C₆ fluoroalcohol-containing solvent whose Fe, Ni, Cr, Al, Zn, Cu, Mg, Li, K, Na and Ca contents are each 500 mass ppb or less (also simply referred to as “fluoroalcohol-containing solvent”), wherein the supercritical fluid has been obtained by controlling temperature and pressure of the fluoroalcohol-containing solvent to be higher than or equal to a critical point of the fluoroalcohol-containing solvent;
(3-3) changing the supercritical fluid to a gas by lowering the pressure inside the chamber; and
(3-4) taking the semiconductor substrate out of the chamber.

In the third embodiment, the fluoroalcohol-containing solvent is preferably a C₂-C₆ fluoroalcohol.

In the third embodiment, the purity of the C₂-C₆ fluoroalcohol is preferably 99.5% or higher.

In the third embodiment, the C₂-C₆ fluoroalcohol is preferably at least one selected from the group consisting of CH₂CHCH₂C(CF₃)₂OH, CHF₂CF₂CH₂OH, (CF₃)₃COH, CH₃(CF₃)₂COH, CF₃CH(OH)CF₃ and CF₃CH₂OH.

In the third embodiment, the water content of the water-based cleaning liquid is preferably 80 mass % or more.

In the third embodiment, the water-based cleaning liquid is preferably water.

According to another preferred embodiment (hereinafter referred to as “fourth embodiment”) of the present invention, the processing method of the semiconductor substrate is carried out through the following steps:
(4-1) supplying the water-based cleaning liquid to the surface of the semiconductor substrate;
(4-2) supplying a water-soluble organic solvent to the surface of the semiconductor substrate to which the water-based cleaning liquid has been attached;
(4-3) moving the semiconductor substrate to which the water-soluble organic solvent has been attached into a chamber, and then, replacing the water-soluble organic solvent attached to the substrate with the supercritical fluid of the C₂-C₆ fluoroalcohol-containing solvent whose Fe, Ni, Cr, Al, Zn, Cu, Mg, Li, K, Na and Ca contents are each 500 mass ppb or less (also simply referred to as “fluoroalcohol-containing solvent”), wherein the supercritical fluid has been obtained by controlling temperature and pressure of the fluoroalcohol-containing solvent to be higher than or equal to a critical point of the fluoroalcohol-containing solvent;
(4-4) changing the supercritical fluid to a gas by lowering the pressure inside the chamber; and
(4-5) taking the semiconductor substrate out of the chamber.

In the fourth embodiment, the fluoroalcohol-containing solvent is preferably a C₂-C₆ fluoroalcohol.

In the fourth embodiment, the purity of the C₂-C₆ fluoroalcohol is preferably 99.5% or higher.

In the fourth embodiment, the C₂-C₆ fluoroalcohol is preferably at least one selected from the group consisting of CH₂CHCH₂C(CF₃)₂OH, CHF₂CF₂CH₂OH, (CF₃)₃COH, CH₃(CF₃)₂COH, CF₃CH(OH)CF₃ and CF₃CH₂OH.

In the fourth embodiment, the water content of the water-based cleaning liquid is preferably 80 mass % or more.

In the fourth embodiment, the water-based cleaning liquid is preferably water.

In the fourth embodiment, the water-soluble organic solvent is preferably a solvent compatible with water at an arbitrary mixing ratio.

In the fourth embodiment, the water-soluble organic solvent is preferably an alcohol.

In the fourth embodiment, the water-soluble organic solvent is preferably at least one selected from the group consisting of 2-propanol and propylene glycol monomethyl ether.

According to another preferred embodiment (hereinafter referred to as “fifth embodiment”) of the present invention, the processing method of the semiconductor substrate comprises the following steps:
(5-1) supplying the water-based cleaning liquid to the surface of the semiconductor substrate;
(5-2) moving the semiconductor substrate to which the water-based cleaning liquid has been attached into a chamber, and then, supplying a water-soluble organic solvent to the surface of the semiconductor substrate to which the water-based cleaning liquid has been attached;
(5-3) replacing the water-soluble organic solvent attached to the substrate with the supercritical fluid of the C₂-C₆ fluoroalcohol-containing solvent whose Fe, Ni, Cr, Al, Zn, Cu, Mg, Li, K, Na and Ca contents are each 500 mass ppb or less (also simply referred to as “fluoroalcohol-containing solvent”), wherein the supercritical fluid has been obtained by controlling temperature and pressure of the fluoroalcohol-containing solvent to be higher than or equal to a critical point of the fluoroalcohol-containing solvent;
(5-4) changing the supercritical fluid to a gas by lowering the pressure inside the chamber; and
(5-5) taking the semiconductor substrate out of the chamber.

In the fifth embodiment, the fluoroalcohol-containing solvent is preferably a C₂-C₆ fluoroalcohol.

In the fifth embodiment, the purity of the C₂-C₆ fluoroalcohol is preferably 99.5% or higher.

In the fifth embodiment, the C₂-C₆ fluoroalcohol is preferably at least one selected from the group consisting of CH₂CHCH₂C(CF₃)₂OH, CHF₂CF₂CH₂OH, (CF₃)₃COH, CH₃(CF₃)₂COH, CF₃CH(OH)CF₃ and CF₃CH₂OH.

In the fifth embodiment, the water content of the water-based cleaning liquid is preferably 80 mass % or more.

In the fifth embodiment, the water-based cleaning liquid is preferably water.

In the fifth embodiment, the water-soluble organic solvent is preferably a solvent compatible with water at an arbitrary mixing ratio.

In the fifth embodiment, the water-soluble organic solvent is preferably an alcohol.

In the fifth embodiment, the water-soluble organic solvent is preferably at least one selected from the group consisting of 2-propanol and propylene glycol monomethyl ether.

Further, the present invention provides a solvent for use in the above processing method, comprising a C₂-C₆ fluoroalcohol, each of Fe, Ni, Cr, Al, Zn, Cu, Mg, Li, K, Na and Ca contents of the solvent being 500 mass ppb or less. The solvent is preferably the C₂-C₆ fluoroalcohol. The purity of the C₂-C₆ fluoroalcohol in the solvent is preferably 99.5% or higher. The C₂-C₆ fluoroalcohol is preferably at least one selected from the group consisting of CH₂CHCH₂C(CF₃)₂OH, CHF₂CF₂CH₂OH, (CF₃)₃COH, CH₃(CF₃)₂COH, CF₃CH(OH)CF₃ and CF₃CH₂OH.

In any of the first to fifth embodiments, it is important that the content of each of Fe, Ni, Cr, Al, Zn, Cu, Mg, Li, K, Na and Ca elements in the fluoroalcohol-containing solvent is 500 mass ppb or less. When the content of each of these elements is more than 500 mass ppb, it is likely that fluorine atoms will be released in the form of e.g. hydrogen fluoride (HF) by change of the solvent to the supercritical fluid.

The content of Fe, Ni, Cr, Al, Zn, Cu, Mg, Li, K, Na, Ca in the fluoroalcohol-containing solvent can be determined by, for example, inductively coupled plasma-atomic emission spectroscopy (ICP-AES), or inductively coupled plasma-mass spectrometry (ICP-MS).

The amount of fluorine atoms released upon change of the solvent to the supercritical fluid can be determined by, for example, ion selective electrode method, chromatography, or ultraviolet visible absorption spectroscopy with zirconium-eriochrome cyanine R or zirconyl alizarin.

It is possible in the present invention to provide the substrate processing method using the supercritical fluid in which the amount of fluorine atoms released is reduced and to provide the solvent for use in the substrate processing method.

### BRIEF DESCRIPTION OF THE DRAWINGS

FIG. 1 is a flowchart for a processing method of a substrate according to a first embodiment of the present invention.

FIG. 2 is a flowchart for a processing method of a substrate according to a second embodiment of the present invention.

FIG. 3 is a flowchart for a processing method of a substrate according to a third embodiment of the present invention.

FIG. 4 is a flowchart for a processing method of a substrate according to a fourth embodiment of the present invention.

FIG. 5 is a flowchart for a processing method of a substrate according to a fifth embodiment of the present invention.

### DETAILED DESCRIPTION OF THE INVENTION

### 1. First Embodiment

As shown in FIG. 1, the first embodiment of the present invention is directed to a processing method of a substrate, including the steps of:
(1-1) supplying a water-based cleaning liquid to a surface of the substrate;
(1-2) supplying a C₂-C₆ fluoroalcohol-containing solvent whose Fe, Ni, Cr, Al, Zn, Cu, Mg, Li. K, Na and Ca contents are each 500 mass ppb or less (also simply referred to as “fluoroalcohol-containing solvent”) to the surface of the substrate to which the water-based cleaning liquid has been attached;
(1-3) moving the substrate to which the fluoroalcohol-containing solvent has been attached into a chamber, and then, controlling temperature and pressure inside the chamber to be higher than or equal to a critical point of the fluoroalcohol-containing solvent to thereby change the fluoroalcohol-containing solvent to a supercritical fluid;
(1-4) changing the supercritical fluid to a gas by lowering the pressure inside the chamber; and
(1-5) taking the substrate out of the chamber.

Step (1-1)

In the step (1-1), the water-based cleaning liquid is supplied to the surface of the substrate.

As an example of the water-based cleaning liquid, there can be used water or an aqueous solution containing at least one kind selected from organic solvent, hydrogen peroxide, ozone, acid, alkali and surfactant in water. In terms of damage to the substrate, the water content of the water-based cleaning liquid is preferably 80 mass % or more. In terms of cleanability, the water-based cleaning liquid is preferably water, particularly preferably ultrapure water.

Further, it is preferable that the content of each of Fe, Ni, Cr, Al, Zn, Cu, Mg, Li. K, Na and Ca elements in the water-based cleaning liquid is 500 mass ppb or less. When the content of each of these elements is more than 500 mass ppb, there is a possibility that the element adheres to and remains on the surface of the substrate in the step (1-1) so as to, when the supercritical fluid of the fluoroalcohol-containing solvent is brought into contact with the surface of the substrate in the subsequent step, cause decomposition of the fluoroalcohol-containing solvent and release fluorine atoms in the supercritical fluid.

The water-based cleaning liquid is preferably the one provided as a commercially available product or prepared by oneself, and purified by distillation, extraction, filtering etc. to a level that each of the Fe, Ni, Cr, Al, Zn, Cu, Mg, Li, K, Na and Ca elements is 500 mass ppb or less.

There is no particular limitation on the technique of supplying the water-based cleaning liquid to the surface of the substrate as long as the water-based cleaning liquid is eventually attached to the surface of the substrate. The water-based cleaning liquid can be supplied in liquid form or in vapor form. More specifically, the water-based cleaning liquid can be supplied to the surface of the substrate by means of a nozzle etc., by exposing the surface of the substrate to a vapor of the water-based cleaning liquid, or by immersing the substrate in the water-based cleaning liquid. At this time, it is feasible to adopt a single wafer process for individual processing of respective substrates or a batch process for simultaneous processing of a plurality of substrates.

Step (1-2)

In the step (1-2), the C₂-C₆ fluoroalcohol-containing solvent whose Fe, Ni, Cr, Al, Zn, Cu, Mg, Li, K, Na and Ca contents are each 500 mass ppb or less (fluoroalcohol-containing solvent) is supplied to the surface of the substrate to which the water-based cleaning liquid has been attached.

When the content of each of these elements in the fluoroalcohol-containing solvent is more than 500 mass ppb, it is likely that the element will cause decomposition of the fluoroalcohol so as to increase the amount of fluorine atoms released in the supercritical fluid. It is preferable that the content of each element is as less as possible. In particular, the content of each element is preferably 350 mass ppb or less, more preferably 100 mass ppb or less.

The fluoroalcohol-containing solvent is preferably the one containing a C₂-C₆ fluoroalcohol provided as a commercially available product or synthesized by oneself, and purified by distillation, extraction, filtering etc. to a level that each of the Fe, Ni, Cr, Al, Zn, Cu, Mg, Li, K, Na and Ca contents is 500 mass ppb or less.

The fluoroalcohol-containing solvent is a solvent containing a C₂-C₆ fluoroalcohol, and optionally any other solvent capable of being dissolved in the fluoroalcohol. As the other solvent, there can preferably be used water or an organic solvent. For easy change to the supercritical fluid, the fluoroalcohol-containing solvent is preferably the C₂-C₆ fluoroalcohol.

The purity of the C₂-C₆ fluoroalcohol is preferably 99.5% or higher. Impurities contained in the fluoroalcohol may undergo decomposition under a high-temperature high-pressure supercritical state to thereby release fluorine atoms. It is thus preferred that the purity of the fluoroalcohol is as high as possible. For example, the C₂-C₆ fluoroalcohol can be obtained with a purity of 99.5% or higher as mentioned above by purification operation such as distillation, filtering or extraction.

The C₂-C₆ fluoroalcohol is preferably a fluoroalcohol represented by the following general formula [1].

RₐCH_{b}OH [1]

In the general formula [1], R is each independently a C₁-C₅ alkyl group in which a part or all of hydrogen atoms may be substituted by fluorine; a is an integer of 1 to 3; b is an integer of 0 to 2; and the sum of a and b is 3.

Examples of the fluoroalcohol represented by the following general formula [1] are CF₃CH₂OH, CHF₂CH₂OH, CF₃CF₂CH₂OH, CHF₂CF₂CH₂OH, CF₃CH(OH)CF₃, CF₃CH(OH)CH₃, CHF₂CH(OH)CHF₂, CH₂FCH(OH)CH₂F, CF₃CF₂CF₂CH₂OH, CHF₂CF₂CF₂CH₂OH, CF₃CHFCF₂CH₂OH, CF₃CH₂CH₂CH₂OH, (CF₃)₂CFCH₂OH, CF₃CF₂CH(OH)CF₃, CF₃CF₂CH(OH)CH₃, (CF₃)₃COH, CH₃(CF₃)₂COH, CF₃(CH₃)₂COH, CF₃CF₂CF₂CF₂CH₂OH, CF₃CF₂CH₂CH₂CH₂OH, CHF₂CF₂CF₂CF₂CH₂OH, CF₃CH₂CH₂CH₂CH₂OH, (CF₃)₂CFCH₂CH₂OH, CF₃CF₂CF₂CH(OH)CF₃, CF₃CF₂CF₂CH(OH)CH₃, CF₃CF₂C(CF₃)₂OH, CF₃CF₂C(CH₃)₂OH, CHF₂CF₂C(CF₃)₂OH, CF₃CF₂CF₂CF₂CF₂CH₂OH, CHF₂CF₂CF₂CF₂CF₂CH₂OH, CF₃CH₂CH₂CH₂CH₂CH₂OH, (CF₃)₂CFCH₂CH₂CH₂OH, CF₃CF₂CF₂CF₂CH(OH)CF₃, CF₃CF₂CF₂CF₂CH(OH)CH₃ and CH₂CHCH₂C(CF₃)₂OH. For easy change to the supercritical fluid, the fluoroalcohol is preferably a primary alcohol having a fluorine substitution rate of 50% or higher, a secondary alcohol having a fluorine substitution ate of 40% or higher or a tertiary alcohol having a fluorine substitution rate of 30% or higher. The term “fluorine substitute rate (%)” refers to a value determined by [the number of fluorine atoms bonded to carbon atoms/(the number of carbon atoms×2+1)×100]. In terms of industrial availability, CH₂CHCH₂C(CF₃)₂OH, CHF₂CF₂CH₂OH, (CF₃)₃COH, CH₃(CF₃)₂COH, CF₃CH(OH)CF₃ and CF₃CH₂OH are preferred because these fluoroalcohols are commonly available as coolants, detergents or the like. In terms of solubility of water or the other solvent, the fluoroalcohol is preferably of 2 or 3 carbon atoms. Particularly preferred are CF₃CH(OH)CF₃ and CF₃CH₂OH.

There is no particular limitation on the technique of supplying the fluoroalcohol-containing solvent to the surface of the substrate as long as the fluoroalcohol-containing solvent is eventually filled on the surface of the substrate. The fluoroalcohol-containing solvent can be supplied in liquid form or in vapor form. More specifically, the fluoroalcohol-containing solvent can be supplied to the surface of the substrate by means of a nozzle etc., by exposing the surface of the substrate to a vapor of the fluoroalcohol-containing solvent, or by immersing the substrate in the fluoroalcohol-containing solvent. At this time, it is feasible to adopt a single wafer process for individual processing of respective substrates or a batch process for simultaneous processing of a plurality of substrates.

Step (1-3)

In the step (1-3), the substrate on which the fluoroalcohol-containing solvent has been filled is moved into the chamber; and the fluoroalcohol-containing solvent is changed to the supercritical fluid by controlling the temperature and pressure inside the chamber to be higher than or equal to the critical point of the fluoroalcohol-containing solvent.

The liquid fluoroalcohol-containing solvent can be changed to the supercritical fluid by heating treatment after moving the substrate on which the fluoroalcohol-containing solvent has been filled in the chamber. The liquid fluoroalcohol-containing solvent can alternatively be changed to the supercritical fluid by pressuring treatment with the supply of a gas of the fluoroalcohol-containing solvent, which has previously been heated to its critical temperature or higher, into the chamber after moving the substrate on which the fluoroalcohol-containing solvent has been filled in the chamber. The heating treatment and the pressurizing treatment may be performed simultaneously.

As the chamber, there can be used any pressure-resistant container capable of withstanding phase change of the fluoroalcohol-containing solvent to the supercritical fluid. The temperature of the chamber may be raised in advance of the placement of the substrate in the chamber. The chamber may be equipped with means for transferring the substrate.

In this step, there takes place phase change of the fluoroalcohol-containing solvent from liquid to the supercritical fluid without vaporization. As the surface of the substrate is continuously covered with the liquid and the supercritical fluid, no pattern collapse occurs in this step.

Step (1-4)

In the step (1-4), the supercritical fluid is changed to gas by lowering the pressure inside the chamber. In other words, the supercritical fluid is gasified without going through a liquid state. Accordingly, no capillary force is exerted on the pattern of the substrate surface so that no pattern collapse occurs. As the surface tension of the supercritical fluid is substantially zero, the capillary force exerted on the pattern is substantially zero. From such a state, the supercritical fluid is gasified without going through a liquid state. It is thus assumed that almost no force acts on the pattern in this step.

Step (1-5)

In the step (1-5), the substrate is taken out of the chamber. The chamber may be equipped with means for transferring the substrate as mentioned above.

### 2. Second Embodiment

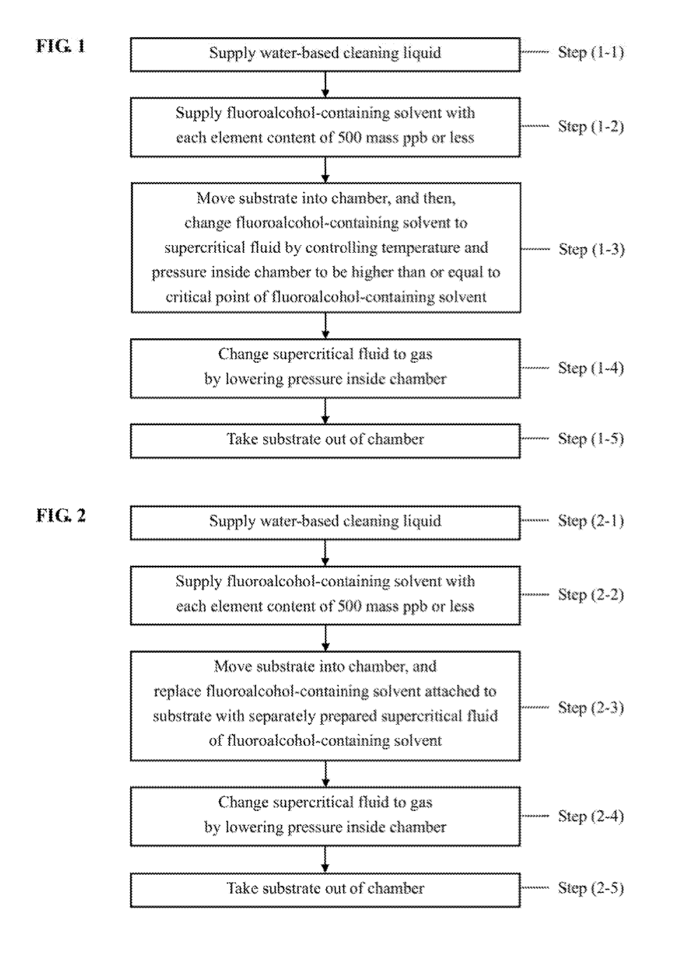

As shown in FIG. 2, the second embodiment of the present invention is directed to a processing method of a substrate, including the following steps:
(2-1) supplying a water-based cleaning liquid to a surface of the substrate;
(2-2) supplying a C₂-C₆ fluoroalcohol-containing solvent whose Fe, Ni, Cr, Al, Zn, Cu, Mg, Li, K, Na and Ca contents are each 500 mass ppb or less (also simply referred to as “fluoroalcohol-containing solvent”) to the surface of the substrate to which the water-based cleaning liquid has been attached;
(2-3) moving the substrate to which the fluoroalcohol-containing solvent has been attached into a chamber, and then, replacing the fluoroalcohol-containing solvent attached to the substrate with a supercritical fluid of the fluoroalcohol-containing solvent, wherein the supercritical fluid has been separately obtained by controlling temperature and pressure of the fluoroalcohol-containing solvent to be higher than or equal to a critical point of the fluoroalcohol-containing solvent;
(2-4) changing the supercritical fluid to a gas by lowering the pressure inside the chamber; and
(2-5) taking the substrate out of the chamber.

Step (2-1)

The step (2-1) is similar to the step (1-1) of the first embodiment.

Step (2-2)

The step (2-2) is similar to the step (1-2) of the first embodiment.

Step (2-3)

In the step (2-3), the substrate on which the fluoroalcohol-containing solvent has been filled is moved into the chamber; and the fluoroalcohol-containing solvent attached to the surface is replaced with the supercritical fluid of the fluoroalcohol-containing solvent, which has been separately obtained by controlling the temperature and pressure of the fluoroalcohol-containing solvent to the critical point or higher.

As mentioned above, the supercritical fluid has been previously and separately obtained by controlling the temperature and pressure of the C₂-C₆ fluoroalcohol-containing solvent, in which the content of each of Fe, Ni, Cr, Al, Zn, Cu, Mg, Li, K, Na and Ca elements is 500 mass ppb or less, to the critical point or higher. When the content of each of these elements is more than 500 mass ppb, it is likely that the element will cause decomposition of the fluoroalcohol so as to increase the amount of fluorine atoms released in the supercritical fluid. It is preferable that the content of each element is as less as possible. In particular, the content of each element is preferably 350 mass ppb or less, more preferably 100 mass ppb or less. The fluoroalcohol-containing solvent used as the supercritical fluid can be of the same composition as or different composition from the fluoroalcohol-containing solvent supplied to the surface of the substrate in the step (2-2).

It is feasible in this step to separately prepare the supercritical fluid of the fluoroalcohol-containing solvent in another pressure-resistant container, which is connected to the chamber via a pipe, by controlling the temperature and pressure of the fluoroalcohol-containing solvent to the critical point or higher, and then, pressure-feed the supercritical fluid into the chamber though the pipe, whereby the fluoroalcohol-containing solvent attached to the substrate is replaced with the separately prepared supercritical fluid of the fluoroalcohol-containing solvent.

The replacement can be done by washing the fluoroalcohol-containing solvent attached to the substrate away with the supercritical fluid, or by dissolving the fluoroalcohol-containing solvent attached to the substrate in the supercritical fluid and holding the resulting mutually dissolved supercritical fluid on the surface of the substrate.

It is herein preferable to supply the supercritical fluid from a nozzle of the chamber, which is connected to the pipe, to the substrate on which the fluoroalcohol-containing solvent has been filled. Such fluid supply may be performed while heating or pressurizing the inside of the chamber.

As the chamber, there can be used any pressure-resistant container capable of maintaining the replaced fluoroalcohol supercritical fluid as it is in a supercritical fluid state. The temperature of the chamber may be raised in advance of the placement of the substrate into the chamber. The chamber may be equipped with means for transferring the substrate.

In this step, there takes place phase change of the fluoroalcohol-containing solvent from liquid to the supercritical fluid without vaporization. As the surface of the substrate is continuously covered with the liquid and the supercritical fluid, no pattern collapse occurs in this step.

Examples of the fluoroalcohol-containing solvent changed to the supercritical fluid are the same as those of the fluoroalcohol-containing solvent used in the step (1-2) of the first embodiment.

Step (2-4)

The step (2-4) is similar to the step (1-4) of the first embodiment.

Step (2-5)

The step (2-2) is similar to the step (1-5) of the first embodiment.

### 3. Third Embodiment

As shown in FIG. 3, the third embodiment of the present invention is directed to a processing method of a substrate, including the steps of:
(3-1) supplying an water-based cleaning liquid to a surface of the substrate;
(3-2) moving the substrate to which the water-based cleaning liquid has been attached into a chamber, and then, replacing the water-based cleaning liquid attached to the substrate with a supercritical fluid of a C₂-C₆ fluoroalcohol-containing solvent whose Fe, Ni, Cr, Al, Zn, Cu, Mg, Li, K, Na and Ca contents are each 500 mass ppb or less (also simply referred to as “fluoroalcohol-containing solvent”), wherein the supercritical fluid has been obtained by controlling temperature and pressure of the fluoroalcohol-containing solvent to be higher than or equal to a critical point of the fluoroalcohol-containing solvent;
(3-3) changing the supercritical fluid to a gas by lowering the pressure inside the chamber; and
(3-4) taking the substrate out of the chamber.

Step (3-1)

The step (3-1) is similar to the step (1-1) of the first embodiment.

Step (3-2)

In the step (3-2), the substrate on which the water-based cleaning liquid has been filled is moved into the chamber; and the water-based cleaning liquid attached to the substrate is replaced with the supercritical fluid of the fluoroalcohol-containing solvent, which has been obtained by controlling the temperature and pressure of the fluoroalcohol-containing solvent to the critical point or higher.

As in the case of the step (2-3) of the second embodiment, the supercritical fluid has been previously obtained by controlling the temperature and pressure of the C₂-C₆ fluoroalcohol-containing solvent, in which the content of each of Fe, Ni, Cr, Al, Zn, Cu, Mg, Li, K, Na and Ca elements is 500 mass ppb or less, to the critical point or higher.

It is feasible in this step to separately prepare the supercritical fluid of the fluoroalcohol-containing solvent in another pressure-resistant container, which is connected to the chamber via a pipe, by controlling the temperature and pressure of the fluoroalcohol-containing solvent to the critical point or higher, and then, pressure-feed the supercritical fluid into the chamber though the pipe, whereby the water-based cleaning liquid attached to the substrate is replaced with the supercritical fluid of the fluoroalcohol-containing solvent.

The replacement can be done by washing the water-based cleaning liquid attached to the substrate away with the supercritical fluid, or by dissolving the water-based cleaning liquid attached to the substrate in the supercritical fluid and holding the resulting mutually dissolved supercritical fluid on the surface of the substrate.

It is herein preferable to supply the supercritical fluid from a nozzle of the chamber, which is connected to the pipe, to the substrate on which the water-based cleaning liquid has been filled. Such fluid supply may be performed while heating or pressurizing the inside of the chamber.

Alternatively, the water-based cleaning liquid attached to the substrate may be replaced with the supercritical fluid of the fluoroalcohol-containing solvent by, after moving the substrate on which the water-based cleaning liquid has been filled into the chamber, supplying the liquid fluoroalcohol-containing solvent from a nozzle of the chamber to the substrate, heating and pressurizing the inside of the chamber to the critical point of the fluoroalcohol-containing solvent or higher and thereby changing the fluoroalcohol-containing solvent to the supercritical fluid.

As the chamber, there can be used any pressure-resistant container capable of maintaining the replaced fluoroalcohol supercritical fluid as it is in a supercritical fluid state. The temperature of the chamber may be raised in advance of the placement of the substrate into the chamber. The chamber may be equipped with means for transferring the substrate.

In this step, there takes place phase change of the fluoroalcohol-containing solvent from liquid to the supercritical fluid without vaporization. As the surface of the substrate is continuously covered with the liquid and the supercritical fluid, no pattern collapse occurs in this step.

Step (3-3)

The step (3-3) is similar to the step (1-4) of the first embodiment.

Step (3-4)

The step (3-4) is similar to the step (1-5) of the first embodiment.

### 4. Fourth Embodiment

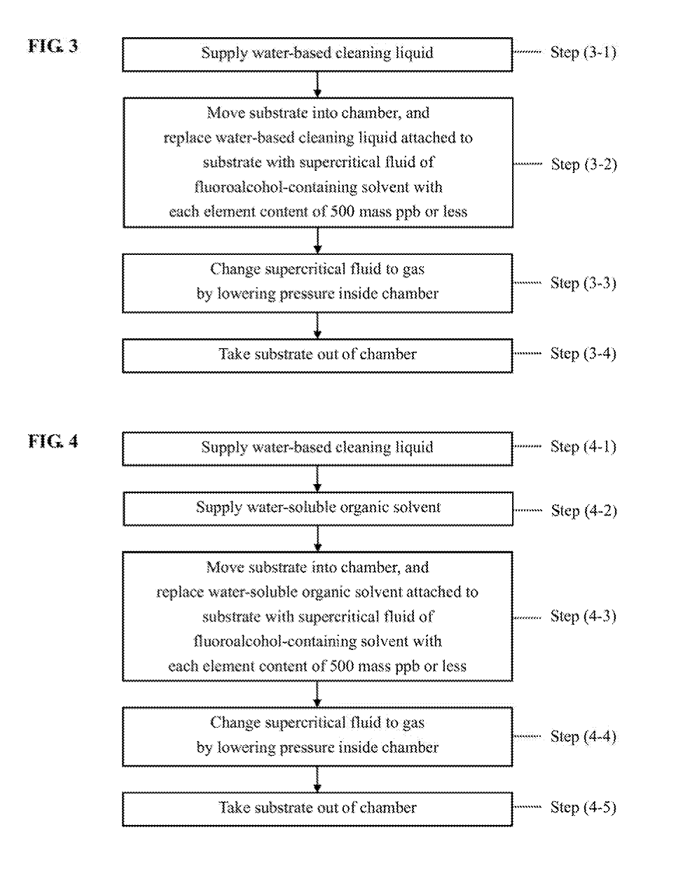

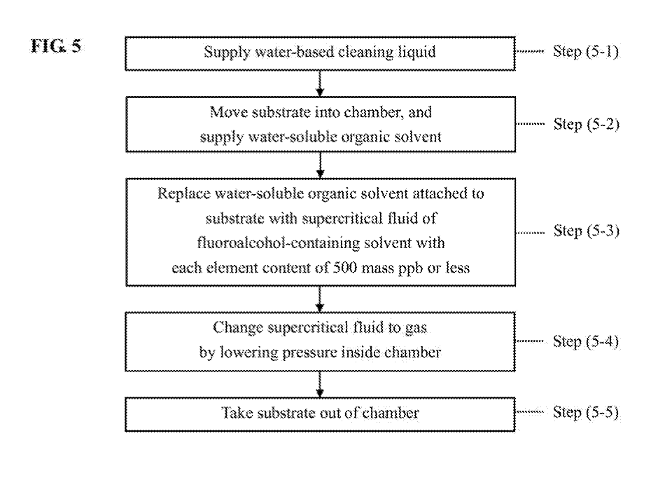

As shown in FIG. 4, the fourth embodiment of the present invention is directed to a processing method of a substrate, including the steps of:
(4-1) supplying a water-based cleaning liquid to a surface of the substrate;
(4-2) supplying a water-soluble organic solvent to the surface of the substrate to which the water-based cleaning liquid has been attached;
(4-3) moving the substrate to which the water-soluble organic solvent has been attached into a chamber, and then, replacing the water-soluble organic solvent attached to the substrate with a supercritical fluid of a C₂-C₆ fluoroalcohol-containing solvent whose Fe, Ni, Cr, Al, Zn, Cu, Mg, Li, K, Na and Ca contents are each 500 mass ppb or less (also simply referred to as “fluoroalcohol-containing solvent”), wherein the supercritical fluid has been obtained by controlling temperature and pressure of the fluoroalcohol-containing solvent to be higher than or equal to a critical point of the fluoroalcohol-containing solvent;
(4-4) changing the supercritical fluid to a gas by lowering the pressure inside the chamber; and
(4-5) taking the substrate out of the chamber.

Step (4-1)

The step (4-1) is similar to the step (1-1) of the first embodiment.

Step (4-2)

In the step (4-2), the water-soluble organic solvent is supplied to the surface of the substrate on which the water-based cleaning liquid has been filled.

The water-soluble organic solvent is a solvent soluble in an amount of 5 parts by weight in 100 parts by weight of water. For easy replacement of the water-based cleaning liquid, it is preferable that the water-soluble organic solvent is compatible with water at an arbitrary mixing ratio. The water-soluble organic solvent may be a mixed medium of organic solvents.

Preferably, the water-soluble organic solvent is at least one selected from the group consisting of isopropyl alcohol (also referred to as 2-propanol or isopropanol) and propylene glycol monomethyl ether because each of these solvents is readily available with less Fe, Ni, Cr, Al, Zn, Cu, Mg, Li, K, Na and Ca contents.

It is preferable that the content of each of Fe, Ni, Cr, Al, Zn, Cu, Mg, Li, K, Na and Ca in the water-soluble organic solvent is 500 mass ppb or less. When the content of each of these elements is more than 500 mass ppb, there is a possibility that the element adheres to and remains on the surface of the substrate in the step (4-2) so as to, when the supercritical fluid of the fluoroalcohol-containing solvent is brought into contact with the surface of the substrate in the subsequent step, cause decomposition of the fluoroalcohol-containing solvent and release fluorine atoms in the supercritical fluid.

The water-soluble organic solvent is preferably the one provided as a commercially available product or prepared by oneself, and purified by distillation, extraction, filtering etc. to a level that each of the Fe, Ni, Cr, Al, Zn, Cu, Mg, Li. K, Na and Ca contents is 500 mass ppb or less.

There is no particular limitation on the technique of supplying the water-soluble organic solvent to the surface of the substrate as long as the water-soluble organic solvent is eventually filled on the surface of the substrate. The water-soluble organic solvent can be supplied in liquid form or in vapor form. More specifically, the water-soluble organic solvent can be supplied to the surface of the substrate by means of a nozzle etc., by exposing the surface of the substrate to a vapor of the water-soluble organic solvent, or by immersing the substrate in the water-soluble organic solvent. At this time, it is feasible to adopt a single wafer process for individual processing of respective substrates or a batch process for simultaneous processing of a plurality of substrates.

Step (4-3)

In the step (4-3), the substrate on which the water-soluble organic solvent has been filled is moved into the chamber; and the water-soluble organic solvent attached to the surface is replaced with the supercritical fluid of the fluoroalcohol-containing solvent, which has been obtained by controlling the temperature and pressure of the fluoroalcohol-containing solvent to the critical point or higher.

As in the case of the step (2-3) of the second embodiment, the supercritical fluid has been previously obtained by controlling the temperature and pressure of the C₂-C₆ fluoroalcohol-containing solvent, in which the content of each of Fe, Ni, Cr, Al, Zn, Cu, Mg, Li, K, Na and Ca elements is 500 mass ppb or less, to the critical point or higher.

It is feasible in this step to separately prepare the supercritical fluid of the fluoroalcohol-containing solvent in another pressure-resistant container, which is connected to the chamber via a pipe, by controlling the temperature and pressure of the fluoroalcohol-containing solvent to the critical point or higher, and then, pressure-feed the supercritical fluid into the chamber though the pipe, whereby the water-soluble organic solvent attached to the substrate is replaced with the supercritical fluid of the fluoroalcohol-containing solvent.

The replacement can be done by washing the water-soluble organic solvent attached to the substrate away with the supercritical fluid, or by dissolving the water-soluble organic solvent attached to the substrate in the supercritical fluid and holding the resulting mutually dissolved supercritical fluid on the surface of the substrate.

It is herein preferable to supply the supercritical fluid from a nozzle of the chamber, which is connected to the pipe, to the substrate on which the water-soluble organic solvent has been filled. Such fluid supply may be performed while heating or pressurizing the inside of the chamber.

Alternatively, the water-soluble organic solvent attached to the substrate may be replaced with the supercritical fluid of the fluoroalcohol-containing solvent by, after moving the substrate on which the water-soluble organic solvent has been filled into the chamber, supplying the liquid fluoroalcohol-containing solvent from a nozzle of the chamber to the substrate, heating and pressurizing the inside of the chamber to the critical point of the fluoroalcohol-containing solvent or higher and thereby changing the fluoroalcohol-containing solvent to the supercritical fluid.

As the chamber, there can be used any pressure-resistant container capable of maintaining the replaced fluoroalcohol supercritical fluid as it is in a supercritical fluid state. The temperature of the chamber may be raised in advance of the placement of the substrate into the chamber. The chamber may be equipped with means for transferring the substrate.

In this step, there takes place phase change of the fluoroalcohol-containing solvent from liquid to the supercritical fluid without vaporization. As the surface of the substrate is continuously covered with the liquid and the supercritical fluid, no pattern collapse occurs in this step.

Step (4-4)

The step (4-4) is similar to the step (1-4) of the first embodiment.

Step (4-5) The step (4-5) is similar to the step (1-5) of the first embodiment.

### 5. Fifth Embodiment

As shown in FIG. 5, the fifth embodiment of the present invention is directed to a processing method of a substrate, including the steps of:
(5-1) supplying a water-based cleaning liquid to a surface of the substrate;
(5-2) moving the substrate to which the water-based cleaning liquid has been attached into a chamber, and then, supplying a water-soluble organic solvent to the surface of the substrate to which the water-based cleaning liquid has been attached;
(5-3) replacing the water-soluble organic solvent attached to the substrate with a supercritical fluid of a C₂-C₆ fluoroalcohol-containing solvent whose Fe, Ni, Cr, Al, Zn, Cu, Mg, Li, K, Na and Ca contents are each 500 mass ppb or less (also simply referred to as “fluoroalcohol-containing solvent”), wherein the supercritical fluid has been obtained by controlling temperature and pressure of the fluoroalcohol-containing solvent to be higher than or equal to a critical point of the fluoroalcohol-containing solvent;
(5-4) changing the supercritical fluid to a gas by lowering the pressure inside the chamber; and
(5-5) taking the substrate out of the chamber

Step (5-1)

The step (5-1) is similar to the step (1-1) of the first embodiment.

Step (5-2)

In the step (5-2), the substrate on which the water-based cleaning liquid has been filled is moved into the chamber; and then, the water-soluble organic solution is supplied to the surface of the substrate. The water-soluble organic solvent used can be of the same kind as that used in the step (4-2) of the fourth embodiment. Further, the water-soluble organic solvent can be supplied by the same technique as in the step (4-2) of the fourth embodiment.

Step (5-3)

The step (5-3) is similar to the step (4-3) of the fourth embodiment.

Step (5-4)

The step (5-4) is similar to the step (1-4) of the first embodiment.

Step (5-5)

The step (5-5) is similar to the step (1-5) of the first embodiment.

### 6. Substrate

The substrate to be processed as the processing target in the first to fifth embodiments is a substrate whose surface has a fine uneven pattern, which may be collapsed due to drying of a cleaning liquid in a conventional wet process, and contain a material affectable by fluorine atoms. Examples of the substrate whose surface contains a material affectable by fluorine atoms are those having Si, Ti, W, Ge, 0, N, C atoms etc. at surfaces thereof (more specifically, those having at surfaces thereof Si, SiC, SiN, SiGe, Ge, TiN, W, InGaAs, SiO₂, SiOC, SiON etc.). Among others, substrates having Si and Ti atoms at surfaces thereof (such as those having Si, SiN, SiO₂, TiN etc. at surfaces thereof) can be processed favorably by the processing method of the present invention. The substrate may be of the type used in a semiconductor wafer, a photomask or a microstructure such as MEMS.

### EXAMPLES

The present invention will be described in more detail below by way of the following examples. It should however be understood that the present invention is not limited to these working examples.

The following examples were conducted to test the processing method for preventing the occurrence of a pattern collapse on the substrate by replacing the liquid retained on the surface of the substrate with the supercritical fluid, or controlling the temperature and pressure of the liquid retained on the surface of the substrate to be higher than or equal to the critical point and thereby changing the liquid to the supercritical fluid, and then, gasifying the supercritical fluid without going through a liquid state. In the respective examples, evaluations were made on the Fe, Ni, Cr, Al, Zn, Cu, Mg, Li, K, Na and Ca contents of the solvent brought as the supercritical fluid into contact with the surface of the substrate and the amount of fluorine atoms released by change of the solvent to the supercritical fluid.

[Evaluation of Fe, Ni, Cr, Al, Zn, Cu, Mg, Li, K, Na and Ca Contents]

The contents of the respective metal elements were measured with an inductively coupled plasma-mass spectrometer (ICP-MS).

[Evaluation of Amount of Fluorine Atoms Released from Solvent During Supercritical Fluid Treatment]

The amount of fluorine atoms released in the supercritical fluid was measured by ion chromatography as follows. After the processing of a wafer, the supercritical fluid inside the chamber was gasified. The solvent was discharged from the chamber and collected by cold trapping in a collecting container cooled with liquid nitrogen. The concentration of fluorine ions in the collected liquid was measured with an ion chromatograph.

[Water-Based Cleaning Liquids]

In the examples and comparative examples, the following water-based cleaning liquids were used.

### <Water-Based Cleaning Liquid 1 (Indicated as “Water 1” in the Tables)>

The water-based cleaning liquid 1 used was pure water in which the contents of Fe, Ni, Cr, Al, Zn, Cu, Mg, Li, K, Na and Ca were each 500 mass ppb or less.

### <Water-Based Cleaning Liquid 2 (Indicated as “Water 2” in the Tables)>

The water-based cleaning liquid 2 used was a mixed liquid of 90 mass % pure water and 10 mass % isopropyl alcohol (hereinafter abbreviated as IPA), in which the contents of Fe, Ni, Cr, Al, Zn, Cu, Mg, Li, K, Na and Ca were each 500 mass ppb or less.

### <Water-Based Cleaning Liquid 3 (Indicated as “Water 3” in the Tables)>

The water-based cleaning liquid 3 used was pure water in which the content of Fe was 800 mass ppb and the contents of the other elements Ni, Cr, Al, Zn, Cu, Mg, Li, K, Na and Ca were each 500 mass ppb or less.

[Water-Soluble Organic Solvents]

The following water-soluble organic solvents were used in the examples and comparative examples.

### <Water-Soluble Organic Solvent 1 (Indicated as “IPA 1” in the Tables)>

The water-soluble organic solvent 1 used was IPA in which the contents of Fe, Ni, Cr, Al, Zn, Cu, Mg, Li, K, Na and Ca were each 500 mass ppb or less.

### <Water-Soluble Organic Solvent 2 (Indicated as “IPA 2” in the Tables)>

The water-soluble organic solvent 2 used was a mixed liquid of 95 mass % IPA and 5 mass % propylene glycol monomethyl ether, in which the contents of Fe, Ni, Cr, Al, Zn, Cu, Mg, Li, K, Na and Ca were each 500 mass ppb or less.

### <Water-Soluble Organic Solvent 3 (Indicated as “IPA 3” in the Tables)>

The water-soluble organic solvent 3 used was IPA in which the content of Fe was 750 mass ppb and the contents of the other elements Ni, Cr, Al, Zn, Cu, Mg, Li, K, Na and Ca were each 500 mass ppb or less.

[Fluoroalcohol-Containing Solvents]

The following fluoroalcohol-containing solvents were used in the examples and comparative examples.
CF₃CH(OH)CF₃ (hereinafter referred to as “HFIP”)
CF₃CH₂OH (hereinafter referred to as “TFEA”)
CH₂CHCH₂C(CF₃)₂OH (hereinafter referred to as “BTHB”)
CHF₂CF₂CH₂OH (hereinafter referred to as “TFPA”)
(CF₃)₃COH (hereinafter referred to as “PFTB”)
CH₃(CF₃)₂COH (hereinafter referred to as “HFTB”)
Mixed solvent of 85 mass % HFIP and 15 mass % TFEA (referred to as “mixed HFTB”)
Each of the HFIP, CF₃CH(OH)CF₃ and TFEA used in the mixed HFTB, TFEA, BTHB, TFPA, PFTB and HFTB had been purified to a gas chromatographic purity of 99.5% or higher by purification operation such as distillation or extraction.

[Substrates]

The following substrates were used in the examples and comparative examples. Since evaluations were made only on the Fe, Ni, Cr, Al, Zn, Cu, Mg, Li, K, Na and Ca contents of the solvent brought as the supercritical fluid into contact with the surface of the substrate and the amount of fluorine atoms released by change of the solvent to the supercritical fluid in the examples and comparative examples, each of the substrates used was an artificial substrate with a smooth surface.
Si substrate without film forming process (hereinafter referred to as “Si substrate”; indicated as “Si” in the tables)
Si substrate having SiO₂ film on surface thereof (hereinafter referred to as “SiO₂ substrate”; indicated as “SiO₂” in the tables)
Si substrate having TiN film on surface thereof (hereinafter referred to as “TiN substrate”; indicated as “TiN” in the tables)
Si substrate having SiN film on surface thereof (hereinafter referred to as “SiN substrate”; indicated as “SiN” in the tables)
Si substrate having SiC film on surface thereof (hereinafter referred to as “SiC substrate”; indicated as “SiC” in the tables)
Si substrate having SiGe film on surface thereof (hereinafter referred to as “SiGe substrate”; indicated as “SiGe” in the tables)
Si substrate having SiOC film on surface thereof (hereinafter referred to as “SiOC substrate”; indicated as “SiOC” in the tables)

### Example 1

In the step (1-1), the water-based cleaning liquid 1 was supplied to the surface of the Si substrate. In the step (1-2), the HFIP with Fe, Ni, Cr, Al, Zn, Cu, Mg, Ni, K, Na and Ca contents shown in TABLE 1 was supplied to the substrate. In the step (1-3), the substrate to which the HFIP had been attached was moved into the chamber; and the HFIP attached to the substrate was changed to the supercritical fluid by controlling the temperature and pressure inside the chamber to be higher than or equal to the critical point of the HFIP. In the step (1-4), the supercritical fluid was changed to a gas by lowering the pressure inside the chamber. In the step (1-5), the substrate was taken out of the chamber. Herein, the pressure for change of the solvent to the supercritical fluid was lower than the pressure for change of carbon dioxide to a supercritical fluid.

The amount of fluorine atoms released during the treatment with the supercritical fluid in the step (1-3) was less than 0.5 vol. ppm. The results are summarized in TABLE 1. It is assumed that, even in the case of using a substrate with a patterned surface, no pattern collapse would occur because the supercritical fluid was gasified without going through a liquid state in the step (1-4).

### Examples 1-2 to 1-17 and Comparative Examples 1-1 to 1-7

The substrates were each processed and evaluated in a similar manner to that of Example 1-1 by varying the substrate, the water-based cleaning liquid and the fluoroalcohol-containing solvent as shown in TABLE 1. The results are summarized in TABLE 1.

TABLE 1

| | | | | | | | | | | | | | | | | Amount |
|---|---|---|---|---|---|---|---|---|---|---|---|---|---|---|---|---|
| | | | | | | | | | | | | | | | | (vol. ppm) |
| | | Water-based | | | | | | | | | | | | | | of F atoms |
| | | cleaning liquid | | | | | | | | | | | | | | released |
| | | used in step (1-1) | | | | | | | | | | | | | | during |
| | | | Element | | | | | | | | | | | | | supercritical |
| | | | content | Fluoroalcohol-containing solvent used in step (1-2) | | | | | | | | | | | | fluid |
| | Sub- | | (mass | | Element content (mass ppb) | | | | | | | | | | | treatment in |
| | strate | Kind | ppb) | Kind | Fe | Ni | Cr | Al | Zn | Cu | Mg | Li | K | Na | Ca | step (1-3) |
| Ex. 1-1 | Si | Water 1 | All <500 | HFIP | <10 | <10 | <10 | <10 | <10 | <10 | <10 | <10 | <10 | <10 | <10 | <0.5 |
| Ex. 1-2 | Si | Water 1 | All <500 | HFIP | 35 | 11 | 28 | 24 | 33 | 12 | 18 | 16 | 25 | 42 | 63 | 1 |
| Ex. 1-3 | Si | Water 1 | All <500 | HFIP | 123 | 151 | 310 | 127 | 58 | 18 | 36 | 48 | 112 | 280 | 301 | 4 |
| Com. Ex. 1-1 | Si | Water 1 | All <500 | HFIP | 621 | 156 | 730 | <10 | 120 | <10 | 15 | 18 | 25 | 230 | 156 | 80 |
| Com. Ex. 1-2 | Si | Water 1 | All <500 | HFIP | 21 | 532 | 15 | 12 | 44 | 682 | <10 | <10 | <10 | 48 | 36 | 68 |
| Com. Ex. 1-3 | Si | Water 1 | All <500 | HFIP | 16 | 13 | 78 | 1011 | 255 | 701 | 400 | 51 | 11 | <10 | <10 | 72 |
| Com. Ex. 1-4 | Si | Water 1 | All <500 | HFIP | 663 | <10 | 428 | <10 | 597 | <10 | 14 | <10 | 127 | 11 | 73 | 101 |
| Com. Ex. 1-5 | Si | Water 1 | All <500 | HFIP | 22 | <10 | 80 | <10 | <10 | <10 | 740 | 903 | 17 | 53 | 103 | 55 |
| Com. Ex. 1-6 | Si | Water 1 | All <500 | HFIP | 15 | <10 | 77 | 18 | 12 | <10 | <10 | <10 | 555 | 15 | 77 | 58 |
| Com. Ex. 1-7 | Si | Water 1 | All <500 | HFIP | 75 | <10 | 91 | <10 | <10 | <10 | <10 | <10 | 15 | 803 | 776 | 97 |
| Ex. 1-4 | Si | Water 2 | All <500 | HFIP | <10 | <10 | <10 | <10 | <10 | <10 | <10 | <10 | <10 | <10 | <10 | <0.5 |
| Ex. 1-5 | Si | Water 3 | Fe 800 | HFIP | <10 | <10 | <10 | <10 | <10 | <10 | <10 | <10 | <10 | <10 | <10 | 2 |
| | | | All | | | | | | | | | | | | | |
| | | | other <500 | | | | | | | | | | | | | |
| Ex. 1-6 | Si | Water 1 | All <500 | Mixed | <10 | <10 | <10 | <10 | <10 | <10 | <10 | <10 | <10 | <10 | <10 | <0.5 |
| | | | | HFIP | | | | | | | | | | | | |
| Ex. 1-7 | Si | Water 1 | All <500 | TFEA | <10 | <10 | <10 | <10 | <10 | <10 | <10 | <10 | <10 | <10 | <10 | <0.5 |
| Ex. 1-8 | Si | Water 1 | All <500 | BTHB | <10 | <10 | <10 | <10 | <10 | <10 | <10 | <10 | <10 | <10 | <10 | <0.5 |
| Ex. 1-9 | Si | Water 1 | All <500 | TFPA | <10 | <10 | <10 | <10 | <10 | <10 | <10 | <10 | <10 | <10 | <10 | <0.5 |
| Ex. 1-10 | Si | Water 1 | All <500 | PFTB | <10 | <10 | <10 | <10 | <10 | <10 | <10 | <10 | <10 | <10 | <10 | <0.5 |
| Ex. 1-11 | Si | Water 1 | All <500 | HFTB | <10 | <10 | <10 | <10 | <10 | <10 | <10 | <10 | <10 | <10 | <10 | <0.5 |
| Ex. 1-12 | SiO₂ | Water 1 | All <500 | HFIP | <10 | <10 | <10 | <10 | <10 | <10 | <10 | <10 | <10 | <10 | <10 | <0.5 |
| Ex. 1-13 | TiN | Water 1 | All <500 | HFIP | <10 | <10 | <10 | <10 | <10 | <10 | <10 | <10 | <10 | <10 | <10 | <0.5 |
| Ex. 1-14 | SiN | Water 1 | All <500 | HFIP | <10 | <10 | <10 | <10 | <10 | <10 | <10 | <10 | <10 | <10 | <10 | <0.5 |
| Ex. 1-15 | SiC | Water 1 | All <500 | HFIP | <10 | <10 | <10 | <10 | <10 | <10 | <10 | <10 | <10 | <10 | <10 | <0.5 |
| Ex. 1-16 | SiGe | Water 1 | All <500 | HFIP | <10 | <10 | <10 | <10 | <10 | <10 | <10 | <10 | <10 | <10 | <10 | <0.5 |
| Ex. 1-17 | SiOC | Water 1 | All <500 | HFIP | <10 | <10 | <10 | <10 | <10 | <10 | <10 | <10 | <10 | <10 | <10 | <0.5 |

As is apparent from the results of Examples 1-1 to 1-3, the amount of fluorine atoms released in the supercritical fluid during the treatment of the substrate with the supercritical fluid in the step (1-3) was quite small when the Fe, Ni, Cr, Al, Zn, Cu, Mg, Li, K, Na and Ca contents of the HFIP (fluoroalcohol-containing solvent) used in the step (1-2) were each 500 mass ppb or less. There was a tendency that the less the content of each metal element in the solvent, the smaller the amount of fluorine atoms released.

As is apparent from the results of Comparative Examples 1-1 to 1-7, on the other hand, the amount of fluorine atoms released in the supercritical fluid was remarkably increased when any of the respective metal element contents of the solvent was more than 500 mass ppb.

It is generally preferable that the amount of fluorine atoms released is as small as possible in view of the facts that: the surface of the substrate is etched by fluorine atoms; and fluorine atoms, when embedded in the semiconductor device such as substrate or pattern, become a cause of deterioration in device performance.

Examples 1-6 to 1-11 were similar to Example 1-1, except that the fluoroalcohol-containing solvent used in the step (1-2) was varied. Each of these examples showed excellent results as in the case of Example 1-1. It has thus been shown that the C₂-C₆ fluoroalcohol-containing solvent, regardless of its kind, is applicable to the first embodiment of the present invention as long as the content of each of Fe, Ni, Cr, Al, Zn, Cu, Mg, Li, K, Na and Ca in the solvent is 500 mass ppb or less.

Examples 1-12 to 1-17 were similar to Example 1-1, except that the processing target was varied from the Si substrate to different kinds of substrates. Each of these examples also showed excellent results as in the case of Example 1-1. It has thus been shown that, regardless of the kind of the substrate, the processing method according to the first embodiment of the present invention is applicable to the substrate even when the surface of the substrate is of material affectable by fluorine atoms.

Examples 1-4 and 1-5 were similar to Example 1-1, except that the water-based cleaning liquid used in the step (1-1) was varied. Each of these examples showed excellent results as in the case of Example 1-1. In Example 1-5 using the water-based cleaning liquid 3 in which the content of Fe was 800 mass ppb, the amount of fluorine atoms released was slightly larger than those in Examples 1-1 and 1-4 each using the water-based cleaning liquid 1 or 2 in which the contents of the metal elements were 500 mass ppb or less. It has thus been shown that it is preferable in the step (1-1) to use the water-based cleaning liquid in which the content of each metal element is mass ppb or less.

### Example 2-1

In the step (2-1), the water-based cleaning liquid 1 was supplied to the surface of the Si substrate. In the step (2-2), the HFIP in which the content of every each of Fe, Ni, Cr, Al, Zn, Cu, Mg, Ni, K, Na and Ca was 500 mass ppb or less (i.e. the same HFIP as that used separately for preparation of the supercritical fluid in the after-mentioned step (2-3)) was supplied to the substrate. In the step (2-3), the substrate to which the HFIP had been attached was moved into the chamber; the supercritical fluid of the HFIP with Fe, Ni, Cr, Al, Zn, Cu, Mg, Ni, K, Na and Ca contents shown in TABLE 2 was separately prepared in another pressure-resistant container, which was connected to the chamber via a pipe, by controlling the temperature and pressure of the HFIP to the critical point or higher; and the thus-obtained supercritical fluid was pressure-fed into the chamber though the pipe so that the HFIP attached to the substrate was replaced with the supercritical fluid. In the step (2-4), the supercritical fluid was changed to a gas by lowering the pressure inside the chamber. In the step (2-5), the substrate was taken out of the chamber. Herein, the pressure for change of the solvent to the supercritical fluid was lower than the pressure for change of carbon dioxide to a supercritical fluid.

The amount of fluorine atoms released during the treatment with the supercritical fluid in the step (2-3) was less than 0.5 vol. ppm. The results are summarized in TABLE 2. It is assumed that, even in the case of using a substrate with a patterned surface, no pattern collapse would occur because the supercritical fluid was gasified without going through a liquid state in the step (2-4).

### Examples 2-2 to 2-18 and Comparative Examples 2-1 to 2-7

The substrates were each processed and evaluated in a similar manner to that of Example 2-1 by varying the substrate, the water-based cleaning liquid and the fluoroalcohol-containing solvent as shown in TABLE 2. The results are summarized in TABLE 2.

TABLE 2

| | | Water-based cleaning | | | | | | | | | |
|---|---|---|---|---|---|---|---|---|---|---|---|
| | | liquid used | | Fluoroalcohol-containing | | | | | | | |
| | | in step (2-1) | | solvent used in step (2-2) | | Fluoroalcohol-containing solvent used as | | | | | |
| | | | Element | | Element | supercritical fluid in step (2-3) | | | | | |
| | | | content | | content | | Element content (mass ppb) | | | | |
| | Substrate | Kind | (mass ppb) | Kind | (mass ppb) | Kind | Fe | Ni | Cr | Al | Zn |
| Ex. 2-1 | Si | water 1 | All <500 | HFIP | All <500 | HFIP | <10 | <10 | <10 | <10 | <10 |
| Ex. 2-2 | Si | water 1 | All <500 | HFIP | All <500 | HFIP | 35 | 11 | 28 | 24 | 33 |
| Ex. 2-3 | Si | water 1 | All <500 | HFIP | All <500 | HFIP | 123 | 151 | 310 | 127 | 58 |
| Com. Ex. 2-1 | Si | water 1 | All <500 | HFIP | All <500 | HFIP | 621 | 156 | 730 | <10 | 120 |
| Com. Ex. 2-2 | Si | water 1 | All <500 | HFIP | All <500 | HFIP | 21 | 532 | 15 | 12 | 44 |
| Com. Ex. 2-3 | Si | water 1 | All <500 | HFIP | All <500 | HFIP | 16 | 13 | 78 | 1011 | 255 |
| Com. Ex. 2-4 | Si | water 1 | All <500 | HFIP | All <500 | HFIP | 663 | <10 | 428 | <10 | 597 |
| Com. Ex. 2-5 | Si | water 1 | All <500 | HFIP | All <500 | HFIP | 22 | <10 | 80 | <10 | <10 |
| Com. Ex. 2-6 | Si | water 1 | All <500 | HFIP | All <500 | HFIP | 15 | <10 | 77 | 18 | 12 |
| Com. Ex. 2-7 | Si | water 1 | All <500 | HFIP | All <500 | HFIP | 75 | <10 | 91 | <10 | <10 |
| Ex. 2-4 | Si | water 2 | All <500 | HFIP | All <500 | HFIP | <10 | <10 | <10 | <10 | <10 |
| Ex. 2-5 | Si | water 3 | Fe 800 | HFIP | All <500 | HFIP | <10 | <10 | <10 | <10 | <10 |
| | | | All other <500 | | | | | | | | |
| Ex. 2-6 | Si | water 1 | All <500 | Mixed | All <500 | Mixed | <10 | <10 | <10 | <10 | <10 |
| | | | | HFIP | | HFIP | | | | | |
| Ex. 2-7 | Si | water 1 | All <500 | TFEA | All <500 | TFEA | <10 | <10 | <10 | <10 | <10 |
| Ex. 2-8 | Si | water 1 | All <500 | BTHB | All <500 | BTHB | <10 | <10 | <10 | <10 | <10 |
| Ex. 2-9 | Si | water 1 | All <500 | TFPA | All <500 | TFPA | <10 | <10 | <10 | <10 | <10 |
| Ex. 2-10 | Si | water 1 | All <500 | PFTB | All <500 | PFTB | <10 | <10 | <10 | <10 | <10 |
| Ex. 2-11 | Si | water 1 | All <500 | HFTB | All <500 | HFTB | <10 | <10 | <10 | <10 | <10 |
| Ex. 2-12 | SiO₂ | water 1 | All <500 | HFIP | All <500 | HFIP | <10 | <10 | <10 | <10 | <10 |
| Ex. 2-13 | TiN | water 1 | All <500 | HFIP | All <500 | HFIP | <10 | <10 | <10 | <10 | <10 |
| Ex. 2-14 | SiN | water 1 | All <500 | HFIP | All <500 | HFIP | <10 | <10 | <10 | <10 | <10 |
| Ex. 2-15 | SiC | water 1 | All <500 | HFIP | All <500 | HFIP | <10 | <10 | <10 | <10 | <10 |
| Ex. 2-16 | SiGe | water 1 | All <500 | HFIP | All <500 | HFIP | <10 | <10 | <10 | <10 | <10 |
| Ex. 2-17 | SiOC | water 1 | All <500 | HFIP | All <500 | HFIP | <10 | <10 | <10 | <10 | <10 |
| Ex. 2-18 | Si | water 1 | All <500 | TFEA used | All <500 | HFIP | <10 | <10 | <10 | <10 | <10 |
| | | | | in step (2-3) | | | | | | | |
| | | | | of Ex. 2-7 | | | | | | | |

| | | | | | | | Amount (vol. ppm) |
|---|---|---|---|---|---|---|---|
| | Fluoroalcohol-containing solvent used as | | | | | | of F atoms released |
| | supercritical fluid in step (2-3) | | | | | | during supercritical |
| | Element content (mass ppb) | | | | | | fluid treatment in |
| | Cu | Mg | Li | K | Na | Ca | step (2-3) |
| Ex. 2-1 | <10 | <10 | <10 | <10 | <10 | <10 | <0.5 |
| Ex. 2-2 | 12 | 18 | 16 | 25 | 42 | 63 | <0.5 |
| Ex. 2-3 | 18 | 36 | 48 | 112 | 280 | 301 | 3 |
| Com. Ex. 2-1 | <10 | 15 | 18 | 25 | 230 | 156 | 55 |
| Com. Ex. 2-2 | 682 | <10 | <10 | <10 | 48 | 36 | 61 |
| Com. Ex. 2-3 | 701 | 400 | 51 | 11 | <10 | <10 | 90 |
| Com. Ex. 2-4 | <10 | 14 | <10 | 127 | 11 | 73 | 153 |
| Com. Ex. 2-5 | <10 | 740 | 903 | 17 | 53 | 103 | 89 |
| Com. Ex. 2-6 | <10 | <10 | <10 | 555 | 15 | 77 | 77 |
| Com. Ex. 2-7 | <10 | <10 | <10 | 15 | 803 | 776 | 100 |
| Ex. 2-4 | <10 | <10 | <10 | <10 | <10 | <10 | <0.5 |
| Ex. 2-5 | <10 | <10 | <10 | <10 | <10 | <10 | 1 |
| Ex. 2-6 | <10 | <10 | <10 | <10 | <10 | <10 | <0.5 |
| Ex. 2-7 | <10 | <10 | <10 | <10 | <10 | <10 | <0.5 |
| Ex. 2-8 | <10 | <10 | <10 | <10 | <10 | <10 | <0.5 |
| Ex. 2-9 | <10 | <10 | <10 | <10 | <10 | <10 | <0.5 |
| Ex. 2-10 | <10 | <10 | <10 | <10 | <10 | <10 | <0.5 |
| Ex. 2-11 | <10 | <10 | <10 | <10 | <10 | <10 | <0.5 |
| Ex. 2-12 | <10 | <10 | <10 | <10 | <10 | <10 | <0.5 |
| Ex. 2-13 | <10 | <10 | <10 | <10 | <10 | <10 | <0.5 |
| Ex. 2-14 | <10 | <10 | <10 | <10 | <10 | <10 | <0.5 |
| Ex. 2-15 | <10 | <10 | <10 | <10 | <10 | <10 | <0.5 |
| Ex. 2-16 | <10 | <10 | <10 | <10 | <10 | <10 | <0.5 |
| Ex. 2-17 | <10 | <10 | <10 | <10 | <10 | <10 | <0.5 |
| Ex. 2-18 | <10 | <10 | <10 | <10 | <10 | <10 | <0.5 |

As is apparent from the results of Examples 2-1 to 2-3, the amount of fluorine atoms released in the supercritical fluid during the treatment of the substrate with the supercritical fluid in the step (2-3) was quite small when the Fe, Ni, Cr, Al, Zn, Cu, Mg, Li, K, Na and Ca contents of the HFIP (fluoroalcohol-containing solvent) used in the step (2-2) and of the HFIP (fluorine-containing solvent) used for preparation of the supercritical fluid in the step (2-3) were each 500 mass ppb or less. There was a tendency that the less the content of each metal element in the solvent, the smaller the amount of fluorine atoms released.

As is apparent from the results of Comparative Examples 2-1 to 2-7, on the other hand, the amount of fluorine atoms released in the supercritical fluid was remarkably increased when any of the respective metal element contents of the HFIP (fluoroalcohol-containing solvent) used in the step (2-2) or the HFIP (fluorine-containing solvent) used for preparation of the supercritical fluid in the step (2-3) was more than 500 mass ppb.

It is generally preferable that the amount of fluorine atoms released is as small as possible in view of the facts that: the surface of the substrate is etched by fluorine atoms; and fluorine atoms, when embedded in the semiconductor device such as substrate or pattern, become a cause of deterioration in device performance.

Examples 2-6 to 2-11 were similar to Example 2-1, except that the kinds of the fluoroalcohol-containing solvents used in the step (2-2) and used as the supercritical fluid in the step (2-3) were varied. Each of these examples showed excellent results as in the case of Example 2-1. It has thus been shown that the C₂-C₆ fluoroalcohol-containing solvent, regardless of its kind, is applicable to the second embodiment of the present invention as long as the content of each of Fe, Ni, Cr, Al, Zn, Cu, Mg, Li, K, Na and Ca in the solvent is 500 mass ppb or less.

Examples 2-12 to 2-17 were similar to Example 2-1, except that the processing target was varied from the Si substrate to different kinds of substrates. Each of these examples also showed excellent results as in the case of Example 2-1. It has thus been shown that, regardless of the kind of the substrate, the processing method according to the second embodiment of the present invention is applicable to the substrate even when the surface of the substrate is of material affectable by fluorine atoms.

Examples 2-4 and 2-5 were similar to Example 2-1, except that the water-based cleaning liquid used in the step (2-1) was varied. Each of these examples showed excellent results as in the case of Example 2-1. In Example 2-5 using the water-based cleaning liquid 3 in which the content of Fe was 800 mass ppb, the amount of fluorine atoms released was slightly larger than those in Examples 2-1 and 2-4 each using the water-based cleaning liquid 1 or 2 in which the contents of the respective metal elements were 500 mass ppb or less. It has thus been shown that it is preferable in the step (2-1) to use the water-based cleaning liquid in which the content of each metal element is mass ppb or less.

Example 2-18 was similar to Example 2-1, except that the TFEA used as the supercritical fluid in the step (2-3) of Example 2-7 was used as the fluoroalcohol-containing solvent in the step (2-2). Namely, the fluoroalcohol-containing solvent used in the step (2-2) and the fluoroalcohol-containing solvent used as the supercritical fluid in the step (2-3) were of different kinds. This experimental example also showed excellent results as in the case of Example 2-1.

### Example 3-1

In the step (3-1), the water-based cleaning liquid 1 was supplied to the surface of the Si substrate. In the step (3-2), the substrate to which the water-based cleaning liquid 1 had been attached was moved into the chamber; the supercritical fluid of the HFIP with Fe, Ni, Cr, Al, Zn, Cu, Mg, Ni, K, Na and Ca contents shown in TABLE 3 was separately prepared in another pressure-resistant container, which was connected to the chamber via a pipe, by controlling the temperature and pressure of the HFIP to the critical point or higher; and the thus-obtained supercritical fluid was pressure-fed into the chamber though the pipe so that the water-based cleaning liquid 1 attached to the substrate was replaced with the supercritical fluid. In the step (3-3), the supercritical fluid was changed to a gas by lowering the pressure inside the chamber. In the step (3-4), the substrate was taken out of the chamber. Herein, the pressure for change of the solvent to the supercritical fluid was lower than the pressure for change of carbon dioxide to a supercritical fluid.

The amount of fluorine atoms released during the treatment with the supercritical fluid in the step (3-2) was less than 0.5 vol. ppm. The results are summarized in TABLE 3. It is assumed that, even in the case of using a substrate with a patterned surface, no pattern collapse would occur because the supercritical fluid was gasified without going through a liquid state in the step (3-3).

### Examples 3-2 to 3-17 and Comparative Examples 3-1 to 3-7

The substrates were each processed and evaluated in a similar manner to that of Example 3-1 by varying the substrate, the water-based cleaning liquid and the fluoroalcohol-containing solvent as shown in TABLE 3. The results are summarized in TABLE 3.

TABLE 3

| | | | | | | | | | | | | | | | | Amount |
|---|---|---|---|---|---|---|---|---|---|---|---|---|---|---|---|---|
| | | | | | | | | | | | | | | | | (vol. ppm) |
| | | | | | | | | | | | | | | | | of F atoms |
| | | Water-based cleaning | | | | | | | | | | | | | | released |
| | | liquid used in | | | | | | | | | | | | | | during |
| | | step (3-1) | | | | | | | | | | | | | | supercritical |
| | | | Element | Fluoroalcohol-containing used as supercritical fluid in step (3-2) | | | | | | | | | | | | fluid |
| | Sub- | | content | | Element content (mass ppb) | | | | | | | | | | | treatment in |
| | strate | Kind | (mass ppb) | Kind | Fe | Ni | Cr | Al | Zn | Cu | Mg | Li | K | Na | Ca | step (3-2) |
| Ex. 3-1 | Si | Water 1 | All <500 | HFIP | <10 | <10 | <10 | <10 | <10 | <10 | <10 | <10 | <10 | <10 | <10 | <0.5 |
| Ex. 3-2 | Si | Water 1 | All <500 | HFIP | 35 | 11 | 28 | 24 | 33 | 12 | 18 | 16 | 25 | 42 | 63 | <0.5 |
| Ex. 3-3 | Si | Water 1 | All <500 | HFIP | 123 | 151 | 310 | 127 | 58 | 18 | 36 | 48 | 112 | 280 | 301 | 5 |
| Com. Ex. 3-1 | Si | Water 1 | All <500 | HFIP | 621 | 156 | 730 | <10 | 120 | <10 | 15 | 18 | 25 | 230 | 156 | 131 |
| Com. Ex. 3-2 | Si | Water 1 | All <500 | HFIP | 21 | 532 | 15 | 12 | 44 | 682 | <10 | <10 | <10 | 48 | 36 | 121 |
| Com. Ex. 3-3 | Si | Water 1 | All <500 | HFIP | 16 | 13 | 78 | 1011 | 255 | 701 | 400 | 51 | 11 | <10 | <10 | 55 |
| Com. Ex. 3-4 | Si | Water 1 | All <500 | HFIP | 663 | <10 | 428 | <10 | 597 | <10 | 14 | <10 | 127 | 11 | 73 | 182 |
| Com. Ex. 3-5 | Si | Water 1 | All <500 | HFIP | 22 | <10 | 80 | <10 | <10 | <10 | 740 | 903 | 17 | 53 | 103 | 74 |
| Com. Ex. 3-6 | Si | Water 1 | All <500 | HFIP | 15 | <10 | 77 | 18 | 12 | <10 | <10 | <10 | 555 | 15 | 77 | 53 |
| Com. Ex. 3-7 | Si | Water 1 | All <500 | HFIP | 75 | <10 | 91 | <10 | <10 | <10 | <10 | <10 | 15 | 803 | 776 | 93 |
| Ex. 3-4 | Si | Water 2 | All <500 | HFIP | <10 | <10 | <10 | <10 | <10 | <10 | <10 | <10 | <10 | <10 | <10 | <0.5 |
| Ex. 3-5 | Si | Water 3 | Fe 800 | HFIP | <10 | <10 | <10 | <10 | <10 | <10 | <10 | <10 | <10 | <10 | <10 | <0.5 |
| | | | All | | | | | | | | | | | | | |
| | | | other <500 | | | | | | | | | | | | | |
| Ex. 3-6 | Si | Water 1 | All <500 | Mixed | <10 | <10 | <10 | <10 | <10 | <10 | <10 | <10 | <10 | <10 | <10 | <0.5 |
| | | | | HFIP | | | | | | | | | | | | |
| Ex. 3-7 | Si | Water 1 | All <500 | TFEA | <10 | <10 | <10 | <10 | <10 | <10 | <10 | <10 | <10 | <10 | <10 | <0.5 |
| Ex. 3-8 | Si | Water 1 | All <500 | BTHB | <10 | <10 | <10 | <10 | <10 | <10 | <10 | <10 | <10 | <10 | <10 | <0.5 |
| Ex. 3-9 | Si | Water 1 | All <500 | TFPA | <10 | <10 | <10 | <10 | <10 | <10 | <10 | <10 | <10 | <10 | <10 | <0.5 |
| Ex. 3-10 | Si | Water 1 | All <500 | PFTB | <10 | <10 | <10 | <10 | <10 | <10 | <10 | <10 | <10 | <10 | <10 | <0.5 |
| Ex. 3-11 | Si | Water 1 | All <500 | HFTB | <10 | <10 | <10 | <10 | <10 | <10 | <10 | <10 | <10 | <10 | <10 | <0.5 |
| Ex. 3-12 | SiO₂ | Water 1 | All <500 | HFIP | <10 | <10 | <10 | <10 | <10 | <10 | <10 | <10 | <10 | <10 | <10 | <0.5 |
| Ex. 3-13 | TiN | Water 1 | All <500 | HFIP | <10 | <10 | <10 | <10 | <10 | <10 | <10 | <10 | <10 | <10 | <10 | <0.5 |
| Ex. 3-14 | SiN | Water 1 | All <500 | HFIP | <10 | <10 | <10 | <10 | <10 | <10 | <10 | <10 | <10 | <10 | <10 | <0.5 |
| Ex. 3-15 | SiC | Water 1 | All <500 | HFIP | <10 | <10 | <10 | <10 | <10 | <10 | <10 | <10 | <10 | <10 | <10 | <0.5 |
| Ex. 3-16 | SiGe | Water 1 | All <500 | HFIP | <10 | <10 | <10 | <10 | <10 | <10 | <10 | <10 | <10 | <10 | <10 | <0.5 |
| Ex. 3-17 | SiOC | Water 1 | All <500 | HFIP | <10 | <10 | <10 | <10 | <10 | <10 | <10 | <10 | <10 | <10 | <10 | <0.5 |

As is apparent from the results of Examples 3-1 to 3-3, the amount of fluorine atoms released in the supercritical fluid during the treatment of the substrate with the supercritical fluid in the step (3-2) was quite small when the Fe, Ni, Cr, Al, Zn, Cu, Mg, Li, K, Na and Ca contents of the HFIP (fluoroalcohol-containing solvent) used for preparation of the supercritical fluid in the step (3-2) were each 500 mass ppb or less. There was a tendency that the less the content of each metal element in the solvent, the smaller the amount of fluorine atoms released.

As is apparent from the results of Comparative Examples 3-1 to 3-7, on the other hand, the amount of fluorine atoms released in the supercritical fluid was remarkably increased when any of the respective metal element contents of the HFIP (fluorine-containing solvent) used for preparation of the supercritical fluid in the step (3-2) was more than 500 mass ppb.

It is generally preferable that the amount of fluorine atoms released is as small as possible in view of the facts that: the surface of the substrate is etched by fluorine atoms; and fluorine atoms, when embedded in the semiconductor device such as substrate or pattern, become a cause of deterioration in device performance.

Examples 3-6 to 3-11 were similar to Example 3-1, except that the fluoroalcohol-containing solvent used as the supercritical fluid in the step (3-2) was varied. Each of these examples showed excellent results as in the case of Example 3-1. It has thus been shown that the C₂-C₆ fluoroalcohol-containing solvent, regardless of its kind, is applicable to the third embodiment of the present invention as long as the content of each of Fe, Ni, Cr, Al, Zn, Cu, Mg, Li, K, Na and Ca in the solvent is 500 mass ppb or less.

Examples 3-12 to 3-17 were similar to Example 3-1, except that the processing target was varied from the Si substrate to different kinds of substrates. Each of these examples also showed excellent results as in the case of Example 3-1. It has thus been shown that, regardless of the kind of the substrate, the processing method according to the third embodiment of the present invention is applicable to the substrate even when the surface of the substrate is of material affectable by fluorine atoms.

Examples 3-4 and 3-5 were similar to Example 3-1, except that the water-based cleaning liquid used in the step (3-1) was varied. Each of these examples showed excellent results as in the case of Example 3-1. In Example 3-5 using the water-based cleaning liquid 3 in which the content of Fe was 800 mass ppb, the amount of fluorine atoms released was slightly larger than those in Examples 3-1 and 3-4 each using the water-based cleaning liquid 1 or 2 in which the contents of the respective metal elements were 500 mass ppb or less. It has thus been shown that it is preferable in the step (3-1) to use the water-based cleaning liquid in which the content of each metal element is mass ppb or less.

### Example 4-1

In the step (4-1), the water-based cleaning liquid 1 was supplied to the surface of the Si substrate. In the step (4-2), the IPA 1 was supplied to the substrate to which the water-based cleaning liquid had been attached. In the step (4-3), the substrate to which the IPA 1 had been attached was moved into the chamber; the supercritical fluid of the HFIP with Fe, Ni, Cr, Al, Zn, Cu, Mg, Ni, K, Na and Ca contents shown in TABLE 4 was separately prepared in another pressure-resistant container, which was connected to the chamber via a pipe, by controlling the temperature and pressure of the HFIP to the critical point or higher;

and the thus-obtained supercritical fluid was pressure-fed into the chamber though the pipe so that the IPA 1 attached to the substrate was replaced with the supercritical fluid. In the step (4-4), the supercritical fluid was changed to a gas by lowering the pressure inside the chamber. In the step (4-5), the substrate was taken out of the chamber. Herein, the pressure for change of the solvent to the supercritical fluid was lower than the pressure for change of carbon dioxide to a supercritical fluid.

The amount of fluorine atoms released during the treatment with the supercritical fluid in the step (4-3) was less than 0.5 vol. ppm. The results are summarized in TABLE 4. It is assumed that, even in the case of using a substrate with a patterned surface, no pattern collapse would occur because the supercritical fluid was gasified without going through a liquid state in the step (4-4).

### Examples 4-2 to 4-19 and Comparative Examples 4-1 to 4-7

The substrates were each processed and evaluated in a similar manner to that of Example 4-1 by varying the substrate, the water-based cleaning liquid, the water-soluble organic solvent and the fluoroalcohol-containing solvent as shown in TABLE 4. The results are summarized in TABLE 4.

TABLE 4

| | | Water-based cleaning | | | | | | | | | |
|---|---|---|---|---|---|---|---|---|---|---|---|
| | | liquid used | | Water-soluble organic | | | | | | | |
| | | in step (4-1) | | solvent used in step (4-2 | | Fluoroalcohol-containing solvent used as | | | | | |
| | | | Element | | Element | supercritical fluid in step (4-3) | | | | | |
| | | | content | | content | | Element content (mass ppb) | | | | |
| | Substrate | Kind | (mass ppb) | Kind | (mass ppb) | Kind | Fe | Ni | Cr | Al | Zn |
| Ex. 4-1 | Si | Water 1 | All <500 | IPA1 | All <500 | HFIP | <10 | <10 | <10 | <10 | <10 |
| Ex. 4-2 | Si | Water 1 | All <500 | IPA1 | All <500 | HFIP | 35 | 11 | 28 | 24 | 33 |
| Ex. 4-3 | Si | Water 1 | All <500 | IPA1 | All <500 | HFIP | 123 | 151 | 310 | 127 | 58 |
| Com. Ex. 4-1 | Si | Water 1 | All <500 | IPA1 | All <500 | HFIP | 621 | 156 | 730 | <10 | 120 |
| Com. Ex. 4-2 | Si | Water 1 | All <500 | IPA1 | All <500 | HFIP | 21 | 532 | 15 | 12 | 44 |
| Com. Ex. 4-3 | Si | Water 1 | All <500 | IPA1 | All <500 | HFIP | 16 | 13 | 78 | 1011 | 255 |
| Com. Ex. 4-4 | Si | Water 1 | All <500 | IPA1 | All <500 | HFIP | 663 | <10 | 428 | <10 | 597 |
| Com. Ex. 4-5 | Si | Water 1 | All <500 | IPA1 | All <500 | HFIP | 22 | <10 | 80 | <10 | <10 |
| Com. Ex. 4-6 | Si | Water 1 | All <500 | IPA1 | All <500 | HFIP | 15 | <10 | 77 | 18 | 12 |
| Com. Ex. 4-7 | Si | Water 1 | All <500 | IPA1 | All <500 | HFIP | 75 | <10 | 91 | <10 | <10 |
| Ex. 4-4 | Si | Water 2 | All <500 | IPA1 | All <500 | HFIP | <10 | <10 | <10 | <10 | <10 |
| Ex. 4-5 | Si | Water 3 | Fe 800 | IPA1 | All <500 | HFIP | <10 | <10 | <10 | <10 | <10 |
| | | | All other <500 | | | | | | | | |
| Ex. 4-6 | Si | Water 1 | All <500 | IPA1 | All <500 | Mixed | <10 | <10 | <10 | <10 | <10 |
| | | | | | | HFIP | | | | | |
| Ex. 4-7 | Si | Water 1 | All <500 | IPA1 | All <500 | TFEA | <10 | <10 | <10 | <10 | <10 |
| Ex. 4-8 | Si | Water 1 | All <500 | IPA1 | All <500 | BTHB | <10 | <10 | <10 | <10 | <10 |
| Ex. 4-9 | Si | Water 1 | All <500 | IPA1 | All <500 | TFPA | <10 | <10 | <10 | <10 | <10 |
| Ex. 4-10 | Si | Water 1 | All <500 | IPA1 | All <500 | PFTB | <10 | <10 | <10 | <10 | <10 |
| Ex. 4-11 | Si | Water 1 | All <500 | IPA1 | All <500 | HFTB | <10 | <10 | <10 | <10 | <10 |
| Ex. 4-12 | SiO₂ | Water 1 | All <500 | IPA1 | All <500 | HFIP | <10 | <10 | <10 | <10 | <10 |
| Ex. 4-13 | TiN | Water 1 | All <500 | IPA1 | All <500 | HFIP | <10 | <10 | <10 | <10 | <10 |
| Ex. 4-14 | SiN | Water 1 | All <500 | IPA1 | All <500 | HFIP | <10 | <10 | <10 | <10 | <10 |
| Ex. 4-15 | SiC | Water 1 | All <500 | IPA1 | All <500 | HFIP | <10 | <10 | <10 | <10 | <10 |
| Ex. 4-16 | SiGe | Water 1 | All <500 | IPA1 | All <500 | HFIP | <10 | <10 | <10 | <10 | <10 |
| Ex. 4-17 | SiOC | Water 1 | All <500 | IPA1 | All <500 | HFIP | <10 | <10 | <10 | <10 | <10 |
| Ex. 4-18 | Si | Water 1 | All <500 | IPA2 | All <500 | HFIP | <10 | <10 | <10 | <10 | <10 |
| Ex. 4-19 | Si | Water 1 | All <500 | IPA3 | Fe 750 | HFIP | <10 | <10 | <10 | <10 | <10 |
| | | | | | All other <500 | | | | | | |

| | | | | | | | Amount (vol. ppm) |
|---|---|---|---|---|---|---|---|
| | Fluoroalcohol-containing solvent used | | | | | | of F atoms released |
| | as supercritical fluid in step (4-3) | | | | | | during supercritical |
| | Element content (mass ppb) | | | | | | fluid treatment in |
| | Cu | Mg | Li | K | Na | Ca | step (4-3) |
| Ex. 4-1 | <10 | <10 | <10 | <10 | <10 | <10 | <0.5 |
| Ex. 4-2 | 12 | 18 | 16 | 25 | 42 | 63 | 1 |
| Ex. 4-3 | 18 | 36 | 48 | 112 | 280 | 301 | 7 |
| Com. Ex. 4-1 | <10 | 15 | 18 | 25 | 230 | 156 | 99 |
| Com. Ex. 4-2 | 682 | <10 | <10 | <10 | 48 | 36 | 96 |
| Com. Ex. 4-3 | 701 | 400 | 51 | 11 | <10 | <10 | 97 |
| Com. Ex. 4-4 | <10 | 14 | <10 | 127 | 11 | 73 | 89 |
| Com. Ex. 4-5 | <10 | 740 | 903 | 17 | 53 | 103 | 103 |
| Com. Ex. 4-6 | <10 | <10 | <10 | 555 | 15 | 77 | 88 |
| Com. Ex. 4-7 | <10 | <10 | <10 | 15 | 803 | 776 | 99 |
| Ex. 4-4 | <10 | <10 | <10 | <10 | <10 | <10 | <0.5 |
| Ex. 4-5 | <10 | <10 | <10 | <10 | <10 | <10 | 2 |
| Ex. 4-6 | <10 | <10 | <10 | <10 | <10 | <10 | <0.5 |
| Ex. 4-7 | <10 | <10 | <10 | <10 | <10 | <10 | <0.5 |
| Ex. 4-8 | <10 | <10 | <10 | <10 | <10 | <10 | <0.5 |
| Ex. 4-9 | <10 | <10 | <10 | <10 | <10 | <10 | <0.5 |
| Ex. 4-10 | <10 | <10 | <10 | <10 | <10 | <10 | <0.5 |
| Ex. 4-11 | <10 | <10 | <10 | <10 | <10 | <10 | <0.5 |
| Ex. 4-12 | <10 | <10 | <10 | <10 | <10 | <10 | <0.5 |
| Ex. 4-13 | <10 | <10 | <10 | <10 | <10 | <10 | <0.5 |
| Ex. 4-14 | <10 | <10 | <10 | <10 | <10 | <10 | <0.5 |
| Ex. 4-15 | <10 | <10 | <10 | <10 | <10 | <10 | <0.5 |
| Ex. 4-16 | <10 | <10 | <10 | <10 | <10 | <10 | <0.5 |
| Ex. 4-17 | <10 | <10 | <10 | <10 | <10 | <10 | <0.5 |
| Ex. 4-18 | <10 | <10 | <10 | <10 | <10 | <10 | <0.5 |
| Ex. 4-19 | <10 | <10 | <10 | <10 | <10 | <10 | 12 |

As is apparent from the results of Examples 4-1 to 4-3, the amount of fluorine atoms released in the supercritical fluid during the treatment of the substrate with the supercritical fluid in the step (4-3) was quite small when the Fe, Ni, Cr, Al, Zn, Cu, Mg, Li, K, Na and Ca contents of the HFIP (fluoroalcohol-containing solvent) used for preparation of the supercritical fluid in the step (4-3) were each 500 mass ppb or less. There was a tendency that the less the content of each metal element in the solvent, the smaller the amount of fluorine atoms released.

As is apparent from the results of Comparative Examples 4-1 to 4-7, on the other hand, the amount of fluorine atoms released in the supercritical fluid was remarkably increased when any of the respective metal element contents of the HFIP (fluorine-containing solvent) used for preparation of the supercritical fluid in the step (4-3) was more than 500 mass ppb.

It is generally preferable that the amount of fluorine atoms released is as small as possible in view of the facts that: the surface of the substrate is etched by fluorine atoms; and fluorine atoms, when embedded in the semiconductor device such as substrate or pattern, become a cause of deterioration in device performance.

Examples 4-6 to 4-11 were similar to Example 4-1, except that the fluoroalcohol-containing solvent used as the supercritical fluid in the step (4-3) was varied. Each of these examples showed excellent results as in the case of Example 4-1. It has thus been shown that the C₂-C₆ fluoroalcohol-containing solvent, regardless of its kind, is applicable to the fourth embodiment of the present invention as long as the content of each of Fe, Ni, Cr, Al, Zn, Cu, Mg, Li, K, Na and Ca in the solvent is 500 mass ppb or less.

Examples 4-12 to 4-17 were similar to Example 4-1, except that the processing target was varied from the Si substrate to different kinds of substrates. Each of these examples also showed excellent results as in the case of Example 4-1. It has thus been shown that, regardless of the kind of the substrate, the processing method according to the fourth embodiment of the present invention is applicable to the substrate even when the surface of the substrate is of material affectable by fluorine atoms.

Examples 4-4 and 4-5 were similar to Example 4-1, except that the water-based cleaning liquid used in the step (4-1) was varied. Each of these examples showed excellent results as in the case of Example 4-1. In Example 4-5 using the water-based cleaning liquid 3 in which the content of Fe was 800 mass ppb, the amount of fluorine atoms released was slightly larger than those in Examples 4-1 and 4-4 each using the water-based cleaning liquid 1 or 2 in which the contents of the respective metal elements were 500 mass ppb or less. It has thus been shown that it is preferable in the step (4-1) to use the water-based cleaning liquid in which the content of each metal element is mass ppb or less.

Examples 4-18 and 4-19 were similar to Example 4-1, except that the water-soluble organic solvent used in the step (4-2) was varied. Each of these examples also showed excellent results as in the case of Example 4-1. In Example 4-19 using the IPA 3 in which the content of Fe was 750 mass ppb, the amount of fluorine atoms released was slightly larger than those in Examples 4-1 and 4-18 each using the IPA 1 or 2 in which the contents of the respective metal elements were 500 mass ppb or less. It has thus been shown that it is preferable in the step (4-2) to use the water-soluble organic solvent in which the content of each metal element is mass ppb or less.

### Example 5-1

In the step (5-1), the water-based cleaning liquid 1 was supplied to the surface of the Si substrate. In the step (5-2), the substrate to which the water-based cleaning liquid had been attached was moved into the chamber; and the IPA 1 was supplied to the surface of the substrate to which the water-based cleaning liquid had been attached in the chamber. In the step (5-3), the supercritical fluid of the HFIP with Fe, Ni, Cr, Al, Zn, Cu, Mg, Ni, K, Na and Ca contents shown in TABLE 5 was separately prepared in another pressure-resistant container, which was connected to the chamber via a pipe, by controlling the temperature and pressure of the HFIP to the critical point or higher; and the thus-obtained supercritical fluid was pressure-fed into the chamber though the pipe so that the IPA 1 attached to the substrate was replaced with the supercritical fluid. In the step (5-4), the supercritical fluid was changed to a gas by lowering the pressure inside the chamber. In the step (5-5), the substrate was taken out of the chamber. Herein, the pressure for change of the solvent to the supercritical fluid was lower than the pressure for change of carbon dioxide to a supercritical fluid.

The amount of fluorine atoms released during the treatment with the supercritical fluid in the step (5-3) was less than 0.5 vol. ppm. The results are summarized in TABLE 5. It is assumed that, even in the case of using a substrate with a patterned surface, no pattern collapse would occur because the supercritical fluid was gasified without going through a liquid state in the step (5-4).

### Examples 5-2 to 5-19 and Comparative Examples 5-1 to 5-7

The substrates were each processed and evaluated in a similar manner to that of Example 5-1 by varying the substrate, the water-based cleaning liquid, the water-soluble organic solvent and the fluoroalcohol-containing solvent as shown in TABLE 5. The results are summarized in TABLE 5.

TABLE 5

| | | Water-based cleaning | | | | | | | | | |
|---|---|---|---|---|---|---|---|---|---|---|---|
| | | liquid used | | Water-soluble organic | | | | | | | |
| | | in step (5-1) | | solvent used in step (5-2) | | Fluoroalcohol-containing solvent used as | | | | | |
| | | | Element | | Element | supercritical fluid in step (5-3) | | | | | |
| | | | content | | content | | Element content (mass ppb) | | | | |
| | Substrate | Kind | (mass ppb) | Kind | (mass ppb) | Kind | Fe | Ni | Cr | Al | Zn |
| Ex. 5-1 | Si | Water 1 | All <500 | IPA1 | All <500 | HFIP | <10 | <10 | <10 | <10 | <10 |
| Ex. 5-2 | Si | Water 1 | All <500 | IPA1 | All <500 | HFIP | 35 | 11 | 28 | 24 | 33 |
| Ex. 5-3 | Si | Water 1 | All <500 | IPA1 | All <500 | HFIP | 123 | 151 | 310 | 127 | 58 |
| Com. Ex. 5-1 | Si | Water 1 | All <500 | IPA1 | All <500 | HFIP | 621 | 156 | 730 | <10 | 120 |
| Com. Ex. 5-2 | Si | Water 1 | All <500 | IPA1 | All <500 | HFIP | 21 | 532 | 15 | 12 | 44 |
| Com. Ex. 5-3 | Si | Water 1 | All <500 | IPA1 | All <500 | HFIP | 16 | 13 | 78 | 1011 | 255 |
| Com. Ex. 5-4 | Si | Water 1 | All <500 | IPA1 | All <500 | HFIP | 663 | <10 | 428 | <10 | 597 |
| Com. Ex. 5-5 | Si | Water 1 | All <500 | IPA1 | All <500 | HFIP | 22 | <10 | 80 | <10 | <10 |
| Com. Ex. 5-6 | Si | Water 1 | All <500 | IPA1 | All <500 | HFIP | 15 | <10 | 77 | 18 | 12 |
| Com. Ex. 5-7 | Si | Water 1 | All <500 | IPA1 | All <500 | HFIP | 75 | <10 | 91 | <10 | <10 |
| Ex. 5-4 | Si | Water 2 | All <500 | IPA1 | All <500 | HFIP | <10 | <10 | <10 | <10 | <10 |
| Ex. 5-5 | Si | Water 3 | Fe 800 | IPA1 | All <500 | HFIP | <10 | <10 | <10 | <10 | <10 |
| | | | All other <500 | | | | | | | | |
| Ex. 5-6 | Si | Water 1 | All <500 | IPA1 | All <500 | Mixed | <10 | <10 | <10 | <10 | <10 |
| | | | | | | HFIP | | | | | |
| Ex. 5-7 | Si | Water 1 | All <500 | IPA1 | All <500 | TFEA | <10 | <10 | <10 | <10 | <10 |
| Ex. 5-8 | Si | Water 1 | All <500 | IPA1 | All <500 | BTHB | <10 | <10 | <10 | <10 | <10 |
| Ex. 5-9 | Si | Water 1 | All <500 | IPA1 | All <500 | TFPA | <10 | <10 | <10 | <10 | <10 |
| Ex. 5-10 | Si | Water 1 | All <500 | IPA1 | All <500 | PFTB | <10 | <10 | <10 | <10 | <10 |
| Ex. 5-11 | Si | Water 1 | All <500 | IPA1 | All <500 | HFTB | <10 | <10 | <10 | <10 | <10 |
| Ex. 5-12 | SiO₂ | Water 1 | All <500 | IPA1 | All <500 | HFIP | <10 | <10 | <10 | <10 | <10 |
| Ex. 5-13 | TiN | Water 1 | All <500 | IPA1 | All <500 | HFIP | <10 | <10 | <10 | <10 | <10 |
| Ex. 5-14 | SiN | Water 1 | All <500 | IPA1 | All <500 | HFIP | <10 | <10 | <10 | <10 | <10 |
| Ex. 5-15 | SiC | Water 1 | All <500 | IPA1 | All <500 | HFIP | <10 | <10 | <10 | <10 | <10 |
| Ex. 5-16 | SiGe | Water 1 | All <500 | IPA1 | All <500 | HFIP | <10 | <10 | <10 | <10 | <10 |
| Ex. 5-17 | SiOC | Water 1 | All <500 | IPA1 | All <500 | HFIP | <10 | <10 | <10 | <10 | <10 |
| Ex. 5-18 | Si | Water 1 | All <500 | IPA2 | All <500 | HFIP | <10 | <10 | <10 | <10 | <10 |
| Ex. 5-19 | Si | Water 1 | All <500 | IPA3 | Fe 750 | HFIP | <10 | <10 | <10 | <10 | <10 |
| | | | | | All other <500 | | | | | | |

| | | | | | | | Amount (vol. ppm) |
|---|---|---|---|---|---|---|---|
| | Fluoroalcohol-containing solvent used | | | | | | of F atoms released |
| | as supercritical fluid in step (5-3) | | | | | | during supercritical |
| | Element content (mass ppb) | | | | | | fluid treatment in |
| | Cu | Mg | Li | K | Na | Ca | step (5-3) |
| Ex. 5-1 | <10 | <10 | <10 | <10 | <10 | <10 | <0.5 |
| Ex. 5-2 | 12 | 18 | 16 | 25 | 42 | 63 | <0.5 |
| Ex. 5-3 | 18 | 36 | 48 | 112 | 280 | 301 | 6 |
| Com. Ex. 5-1 | <10 | 15 | 18 | 25 | 230 | 156 | 88 |
| Com. Ex. 5-2 | 682 | <10 | <10 | <10 | 48 | 36 | 68 |
| Com. Ex. 5-3 | 701 | 400 | 51 | 11 | <10 | <10 | 71 |
| Com. Ex. 5-4 | <10 | 14 | <10 | 127 | 11 | 73 | 105 |
| Com. Ex. 5-5 | <10 | 740 | 903 | 17 | 53 | 103 | 54 |
| Com. Ex. 5-6 | <10 | <10 | <10 | 555 | 15 | 77 | 53 |
| Com. Ex. 5-7 | <10 | <10 | <10 | 15 | 803 | 776 | 111 |
| Ex. 5-4 | <10 | <10 | <10 | <10 | <10 | <10 | <0.5 |
| Ex. 5-5 | <10 | <10 | <10 | <10 | <10 | <10 | 2 |
| Ex. 5-6 | <10 | <10 | <10 | <10 | <10 | <10 | <0.5 |
| Ex. 5-7 | <10 | <10 | <10 | <10 | <10 | <10 | <0.5 |
| Ex. 5-8 | <10 | <10 | <10 | <10 | <10 | <10 | <0.5 |
| Ex. 5-9 | <10 | <10 | <10 | <10 | <10 | <10 | <0.5 |
| Ex. 5-10 | <10 | <10 | <10 | <10 | <10 | <10 | <0.5 |
| Ex. 5-11 | <10 | <10 | <10 | <10 | <10 | <10 | <0.5 |
| Ex. 5-12 | <10 | <10 | <10 | <10 | <10 | <10 | <0.5 |
| Ex. 5-13 | <10 | <10 | <10 | <10 | <10 | <10 | <0.5 |
| Ex. 5-14 | <10 | <10 | <10 | <10 | <10 | <10 | <0.5 |
| Ex. 5-15 | <10 | <10 | <10 | <10 | <10 | <10 | <0.5 |
| Ex. 5-16 | <10 | <10 | <10 | <10 | <10 | <10 | <0.5 |
| Ex. 5-17 | <10 | <10 | <10 | <10 | <10 | <10 | <0.5 |
| Ex. 5-18 | <10 | <10 | <10 | <10 | <10 | <10 | <0.5 |
| Ex. 5-19 | <10 | <10 | <10 | <10 | <10 | <10 | 11 |

As is apparent from the results of Examples 5-1 to 5-3, the amount of fluorine atoms released in the supercritical fluid during the treatment of the substrate with the supercritical fluid in the step (5-3) was quite small when the Fe, Ni, Cr, Al, Zn, Cu, Mg, Li, K, Na and Ca contents of the HFIP (fluoroalcohol-containing solvent) used for preparation of the supercritical fluid in the step (5-3) were each 500 mass ppb or less. There was a tendency that the less the content of each metal element in the solvent, the smaller the amount of fluorine atoms released.

As is apparent from the results of Comparative Examples 5-1 to 5-7, on the other hand, the amount of fluorine atoms released in the supercritical fluid was remarkably increased when any of the respective metal element contents of the HFIP (fluorine-containing solvent) used for preparation of the supercritical fluid in the step (5-3) was more than 500 mass ppb.

It is generally preferable that the amount of fluorine atoms released is as small as possible in view of the facts that: the surface of the substrate is etched by fluorine atoms; and fluorine atoms, when embedded in the semiconductor device such as substrate or pattern, become a cause of deterioration in device performance.

Examples 5-6 to 5-11 were similar to Example 5-1, except that the fluoroalcohol-containing solvent used as the supercritical fluid in the step (5-3) was varied. Each of these examples showed excellent results as in the case of Example 5-1. It has thus been shown that the C₂-C₆ fluoroalcohol-containing solvent, regardless of its kind, is applicable to the fifth embodiment of the present invention as long as the content of each of Fe, Ni, Cr, Al, Zn, Cu, Mg, Li, K, Na and Ca in the solvent is 500 mass ppb or less.

Examples 5-12 to 5-17 were similar to Example 5-1, except that the processing target was varied from the Si substrate to different kinds of substrates. Each of these examples also showed excellent results as in the case of Example 5-1. It has thus been shown that, regardless of the kind of the substrate, the processing method according to the fifth embodiment of the present invention is applicable to the substrate even when the surface of the substrate is of material affectable by fluorine atoms.

Examples 5-4 and 5-5 were similar to Example 5-1, except that the water-based cleaning liquid used in the step (4-1) was varied. Each of these examples showed excellent results as in the case of Example 5-1. In Example 5-5 using the water-based cleaning liquid 3 in which the content of Fe was 800 mass ppb, the amount of fluorine atoms released was slightly larger than those in Examples 5-1 and 5-4 each using the water-based cleaning liquid 1 or 2 in which the contents of the respective metal elements were 500 mass ppb or less. It has thus been shown that it is preferable in the step (5-1) to use the water-based cleaning liquid in which the content of each metal element is mass ppb or less.

Examples 5-18 and 5-19 were similar to Example 5-1, except that the water-soluble organic solvent used in the step (5-2) was varied. Each of these examples also showed excellent results as in the case of Example 5-1. In Example 5-19 using the IPA 3 in which the content of Fe was 750 mass ppb, the amount of fluorine atoms released was slightly larger than those in Examples 5-1 and 5-18 each using the IPA 1 or 2 in which the contents of the respective metal elements were 500 mass ppb or less. It has thus been shown that it is preferable in the step (5-2) to use the water-soluble organic solvent in which the content of each metal element is mass ppb or less.

### Example 3-18

The substrate was processed in the same manner as in Example 3-1, except that, in the step (3-2), the substrate on which the water-based cleaning liquid 1 had been attached was moved into the chamber; and the water-based cleaning liquid attached to the surface was replaced with the supercritical fluid of the fluoroalcohol-containing solvent by supplying the liquid HFIP to the substrate and heating/pressurizing the inside of the chamber to be higher than or equal to the critical point of the HFIP to change the HFIP to the supercritical fluid. The substrate was then evaluated in the same manner as in Example 3-1. The results are summarized in TABLE 6. The liquid HFIP used was the same as that used for preparation of the supercritical fluid in the step (3-2) of Example 3-1. The Fe, Ni, Cr, Al, Zn, Cu, Mg, Li, K, Na and Ca contents of the liquid HFIP were as shown in TABLE 3.

### Examples 3-19 to 3-34 and Comparative Examples 3-8 to 3-14

The substrates were each processed and evaluated in a manner shown in TABLE 6. The results are summarized in TABLE 6.

TABLE 6

| | | | | Amount (vol. |
|---|---|---|---|---|
| | | | | ppm) of F |
| | | | | atoms released |
| | | | | during super- |
| | | | | critical fluid |
| | Fluoroalcohol-containing solvent | | Steps other than step | treatment in |
| | supplied as liquid in step (3-2) | Step (3-2) | (3-2) | step (3-2) |
| Ex. 3-18 | Same solvent as used in step (3-2) of Ex. 3-1 | Liquid fluoroalcohol-containing | Same as in Ex. 3-1 | <0.5 |
| | | solvent was supplied and changed | | |
| | | to supercritical fluid by heating | | |
| | | and pressurizing in chamber, | | |
| | | thereby replacing fluoroalcohol- | | |
| | | containing solvent with | | |
| | | supercritical fluid | | |
| Ex. 3-19 | Same solvent as used in step (3-2) of Ex. 3-2 | Same as in Ex. 3-18 | Same as in Ex. 3-2 | <0.5 |
| Ex. 3-20 | Same solvent as used in step (3-2) of Ex. 3-3 | Same as in Ex. 3-18 | Same as in Ex. 3-3 | 1 |
| Com. Ex. 3-8 | Same solvent as used in step (3-2) of Com. Ex. 3-1 | Same as in Ex. 3-18 | Same as in Com. Ex. 3-1 | 92 |
| Com. Ex. 3-9 | Same solvent as used in step (3-2) of Com. Ex. 3-2 | Same as in Ex. 3-18 | Same as in Com. Ex. 3-2 | 71 |
| Com. Ex. 3-10 | Same solvent as used in step (3-2) of Com. Ex. 3-3 | Same as in Ex. 3-18 | Same as in Com. Ex. 3-3 | 71 |
| Com. Ex. 3-11 | Same solvent as used in step (3-2) of Com. Ex. 3-4 | Same as in Ex. 3-18 | Same as in Com. Ex. 3-4 | 125 |
| Com. Ex. 3-12 | Same solvent as used in step (3-2) of Com. Ex. 3-5 | Same as in Ex. 3-18 | Same as in Com. Ex. 3-5 | 99 |
| Com. Ex. 3-13 | Same solvent as used in step (3-2) of Com. Ex. 3-6 | Same as in Ex. 3-18 | Same as in Com. Ex. 3-6 | 57 |
| Com. Ex. 3-14 | Same solvent as used in step (3-2) of Com. Ex. 3-7 | Same as in Ex. 3-18 | Same as in Com. Ex. 3-7 | 58 |
| Ex. 3-21 | Same solvent as used in step (3-2) of Ex. 3-4 | Same as in Ex. 3-18 | Same as in Ex. 3-4 | <0.5 |
| Ex. 3-22 | Same solvent as used in step (3-2) of Ex. 3-5 | Same as in Ex. 3-18 | Same as in Ex. 3-5 | 3 |
| Ex. 3-23 | Same solvent as used in step (3-2) of Ex. 3-6 | Same as in Ex. 3-18 | Same as in Ex. 3-6 | <0.5 |
| Ex. 3-24 | Same solvent as used in step (3-2) of Ex. 3-7 | Same as in Ex. 3-18 | Same as in Ex. 3-7 | <0.5 |
| Ex. 3-25 | Same solvent as used in step (3-2) of Ex. 3-8 | Same as in Ex. 3-18 | Same as in Ex. 3-8 | <0.5 |
| Ex. 3-26 | Same solvent as used in step (3-2) of Ex. 3-9 | Same as in Ex. 3-18 | Same as in Ex. 3-9 | <0.5 |
| Ex. 3-27 | Same solvent as used in step (3-2) of Ex. 3-10 | Same as in Ex. 3-18 | Same as in Ex. 3-10 | <0.5 |
| Ex. 3-28 | Same solvent as used in step (3-2) of Ex. 3-11 | Same as in Ex. 3-18 | Same as in Ex. 3-11 | <0.5 |
| Ex. 3-29 | Same solvent as used in step (3-2) of Ex. 3-12 | Same as in Ex. 3-18 | Same as in Ex. 3-12 | <0.5 |
| Ex. 3-30 | Same solvent as used in step (3-2) of Ex. 3-13 | Same as in Ex. 3-18 | Same as in Ex. 3-13 | <0.5 |
| Ex. 3-31 | Same solvent as used in step (3-2) of Ex. 3-14 | Same as in Ex. 3-18 | Same as in Ex. 3-14 | <0.5 |
| Ex. 3-32 | Same solvent as used in step (3-2) of Ex. 3-15 | Same as in Ex. 3-18 | Same as in Ex. 3-15 | <0.5 |
| Ex. 3-33 | Same solvent as used in step (3-2) of Ex. 3-16 | Same as in Ex. 3-18 | Same as in Ex. 3-16 | <0.5 |
| Ex. 3-34 | Same solvent as used in step (3-2) of Ex. 3-17 | Same as in Ex. 3-18 | Same as in Ex. 3-17 | <0.5 |

### Example 4-20

The substrate was processed in the same manner as in Example 4-1, except that, in the step (4-3), the substrate on which the IPA 1 had been attached was moved into the chamber; and the water-based cleaning liquid attached to the surface was replaced with the supercritical fluid of the fluoroalcohol-containing solvent by supplying the liquid HFIP to the substrate and heating/pressurizing the inside of the chamber to be higher than or equal to the critical point of the HFIP to thereby change the HFIP to the supercritical fluid. The substrate was then evaluated in the same manner as in Example 3-1. The results are summarized in TABLE 7. The liquid HFIP used was the same as that used for preparation of the supercritical fluid in the step (4-3) of Example 4-1. The Fe, Ni, Cr, Al, Zn, Cu, Mg, Li, K, Na and Ca contents of the liquid HFIP were as shown in TABLE 4.

### Examples 4-21 to 4-38 and Comparative Examples 4-8 to 4-14

The substrates were each processed and evaluated in a manner shown in TABLE 7. The results are summarized shown in TABLE 7.

TABLE 7

| | | | | Amount (vol. |
|---|---|---|---|---|
| | | | | ppm) of F |
| | | | | atoms released |
| | | | | during super- |
| | | | | critical fluid |
| | Fluoroalcohol-containing solvent | | Steps other than step | treatment in |
| | supplied as liquid in step (4-3) | Step (4-3) | (4-3) | step (4-3) |
| Ex. 4-20 | Same solvent as used in step (4-3) of Ex. 4-1 | Liquid fluoroalcohol-containing | Same as in Ex. 4-1 | <0.5 |
| | | solvent was supplied and changed | | |
| | | to supercritical fluid by heating | | |
| | | and pressurizing in chamber, | | |
| | | thereby replacing fluoroalcohol- | | |
| | | containing solvent with | | |
| | | supercritical fluid | | |
| Ex. 4-21 | Same solvent as used in step (4-3) of Ex. 4-2 | Same as in Ex. 4-20 | Same as in Ex. 4-2 | <0.5 |
| Ex. 4-22 | Same solvent as used in step (4-3) of Ex. 4-3 | Same as in Ex. 4-20 | Same as in Ex. 4-3 | 2 |
| Com. Ex. 4-8 | Same solvent as used in step (4-3) of Com. Ex. 4-1 | Same as in Ex. 4-20 | Same as in Com. Ex. 4-1 | 83 |
| Com. Ex. 4-9 | Same solvent as used in step (4-3) of Com. Ex. 4-2 | Same as in Ex. 4-20 | Same as in Com. Ex. 4-2 | 78 |
| Com. Ex. 4-10 | Same solvent as used in step (4-3) of Com. Ex. 4-3 | Same as in Ex. 4-20 | Same as in Com. Ex. 4-3 | 59 |
| Com. Ex. 4-11 | Same solvent as used in step (4-3) of Com. Ex. 4-4 | Same as in Ex. 4-20 | Same as in Com. Ex. 4-4 | 152 |
| Com. Ex. 4-12 | Same solvent as used in step (4-3) of Com. Ex. 4-5 | Same as in Ex. 4-20 | Same as in Com. Ex. 4-5 | 57 |
| Com. Ex. 4-13 | Same solvent as used in step (4-3) of Com. Ex. 4-6 | Same as in Ex. 4-20 | Same as in Com. Ex. 4-6 | 99 |
| Com. Ex. 4-14 | Same solvent as used in step (4-3) of Com. Ex. 4-7 | Same as in Ex. 4-20 | Same as in Com. Ex. 4-7 | 80 |
| Ex. 4-23 | Same solvent as used in step (4-3) of Ex. 4-4 | Same as in Ex. 4-20 | Same as in Ex. 4-4 | <0.5 |
| Ex. 4-24 | Same solvent as used in step (4-3) of Ex. 4-5 | Same as in Ex. 4-20 | Same as in Ex. 4-5 | 3 |
| Ex. 4-25 | Same solvent as used in step (4-3) of Ex. 4-6 | Same as in Ex. 4-20 | Same as in Ex. 4-6 | <0.5 |
| Ex. 4-26 | Same solvent as used in step (4-3) of Ex. 4-7 | Same as in Ex. 4-20 | Same as in Ex. 4-7 | <0.5 |
| Ex. 4-27 | Same solvent as used in step (4-3) of Ex. 4-8 | Same as in Ex. 4-20 | Same as in Ex. 4-8 | <0.5 |
| Ex. 4-28 | Same solvent as used in step (4-3) of Ex. 4-9 | Same as in Ex. 4-20 | Same as in Ex. 4-9 | <0.5 |
| Ex. 4-29 | Same solvent as used in step (4-3) of Ex. 4-10 | Same as in Ex. 4-20 | Same as in Ex. 4-10 | <0.5 |
| Ex. 4-30 | Same solvent as used in step (4-3) of Ex. 4-11 | Same as in Ex. 4-20 | Same as in Ex. 4-11 | <0.5 |
| Ex. 4-31 | Same solvent as used in step (4-3) of Ex. 4-12 | Same as in Ex. 4-20 | Same as in Ex. 4-12 | <0.5 |
| Ex. 4-32 | Same solvent as used in step (4-3) of Ex. 4-13 | Same as in Ex. 4-20 | Same as in Ex. 4-13 | <0.5 |
| Ex. 4-33 | Same solvent as used in step (4-3) of Ex. 4-14 | Same as in Ex. 4-20 | Same as in Ex. 4-14 | <0.5 |
| Ex. 4-34 | Same solvent as used in step (4-3) of Ex. 4-15 | Same as in Ex. 4-20 | Same as in Ex. 4-15 | <0.5 |
| Ex. 4-35 | Same solvent as used in step (4-3) of Ex. 4-16 | Same as in Ex. 4-20 | Same as in Ex. 4-16 | <0.5 |
| Ex. 4-36 | Same solvent as used in step (4-3) of Ex. 4-17 | Same as in Ex. 4-20 | Same as in Ex. 4-17 | <0.5 |
| Ex. 4-37 | Same solvent as used in step (4-3) of Ex. 4-18 | Same as in Ex. 4-20 | Same as in Ex. 4-18 | <0.5 |
| Ex. 4-38 | Same solvent as used in step (4-3) of Ex. 4-19 | Same as in Ex. 4-20 | Same as in Ex. 4-19 | 6 |

### Example 5-20

The substrate was processed in the same manner as in Example 5-1, except that, in the step (5-3), the water-based cleaning liquid attached to the surface was replaced with the supercritical fluid of the fluoroalcohol-containing solvent by supplying the liquid HFIP to the substrate to which the IPA 1 had been attached and heating/pressurizing the inside of the chamber to be higher than or equal to the critical point of the HFIP to thereby change the HFIP to the supercritical fluid. The substrate was then evaluated in the same manner as in Example 3-1. The results are summarized in TABLE 7. The liquid HFIP used was the same as that used for preparation of the supercritical fluid in the step (4-3) of Example 4-1. The Fe, Ni, Cr, Al, Zn, Cu, Mg, Li, K, Na and Ca contents of the liquid HFIP were as shown in TABLE 5.

### Examples 5-21 to 5-38 and Comparative Examples 5-8 to 5-14

The substrates were each processed and evaluated in a manner shown in TABLE 8. The results are summarized in TABLE 8.

TABLE 8

| | | | | Amount (vol. |
|---|---|---|---|---|
| | | | | ppm) of F |
| | | | | atoms released |
| | | | | during super- |
| | | | | critical fluid |
| | Fluoroalcohol-containing solvent | | Steps other than step | treatment in |
| | supplied as liquid in step (5-3) | Step (5-3) | (5-3) | step (5-3) |
| Ex. 5-20 | Same solvent as used in step (5-3) of Ex. 5-1 | Liquid fluoroalcohol-containing | Same as in Ex. 5-1 | <0.5 |
| | | solvent was supplied and changed | | |
| | | to supercritical fluid by heating | | |
| | | and pressurizing in chamber, | | |
| | | thereby replacing fluoroalcohol- | | |
| | | containing solvent with | | |
| | | supercritical fluid | | |
| Ex. 5-21 | Same solvent as used in step (5-3) of Ex. 5-2 | Same as in Ex. 5-20 | Same as in Ex. 5-2 | <0.5 |
| Ex. 5-22 | Same solvent as used in step (5-3) of Ex. 5-3 | Same as in Ex. 5-20 | Same as in Ex. 5-3 | 4 |
| Com. Ex. 5-8 | Same solvent as used in step (5-3) of Com. Ex. 5-1 | Same as in Ex. 5-20 | Same as in Com. Ex. 5-1 | 98 |
| Com. Ex. 5-9 | Same solvent as used in step (5-3) of Com. Ex. 5-2 | Same as in Ex. 5-20 | Same as in Com. Ex. 5-2 | 86 |
| Com. Ex. 5-10 | Same solvent as used in step (5-3) of Com. Ex. 5-3 | Same as in Ex. 5-20 | Same as in Com. Ex. 5-3 | 135 |
| Com. Ex. 5-11 | Same solvent as used in step (5-3) of Com. Ex. 5-4 | Same as in Ex. 5-20 | Same as in Com. Ex. 5-4 | 150 |
| Com. Ex. 5-12 | Same solvent as used in step (5-3) of Com. Ex. 5-5 | Same as in Ex. 5-20 | Same as in Com. Ex. 5-5 | 107 |
| Com. Ex. 5-13 | Same solvent as used in step (5-3) of Com. Ex. 5-6 | Same as in Ex. 5-20 | Same as in Com. Ex. 5-6 | 118 |
| Com. Ex. 5-14 | Same solvent as used in step (5-3) of Com. Ex. 5-7 | Same as in Ex. 5-20 | Same as in Com. Ex. 5-7 | 106 |
| Ex. 5-23 | Same solvent as used in step (5-3) of Ex. 5-4 | Same as in Ex. 5-20 | Same as in Ex. 5-4 | <0.5 |
| Ex. 5-24 | Same solvent as used in step (5-3) of Ex. 5-5 | Same as in Ex. 5-20 | Same as in Ex. 5-5 | 5 |
| Ex. 5-25 | Same solvent as used in step (5-3) of Ex. 5-6 | Same as in Ex. 5-20 | Same as in Ex. 5-6 | <0.5 |
| Ex. 5-26 | Same solvent as used in step (5-3) of Ex. 5-7 | Same as in Ex. 5-20 | Same as in Ex. 5-7 | <0.5 |
| Ex. 5-27 | Same solvent as used in step (5-3) of Ex. 5-8 | Same as in Ex. 5-20 | Same as in Ex. 5-8 | <0.5 |
| Ex. 5-28 | Same solvent as used in step (5-3) of Ex. 5-9 | Same as in Ex. 5-20 | Same as in Ex. 5-9 | <0.5 |
| Ex. 5-29 | Same solvent as used in step (5-3) of Ex. 5-10 | Same as in Ex. 5-20 | Same as in Ex. 5-10 | <0.5 |
| Ex. 5-30 | Same solvent as used in step (5-3) of Ex. 5-11 | Same as in Ex. 5-20 | Same as in Ex. 5-11 | <0.5 |
| Ex. 5-31 | Same solvent as used in step (5-3) of Ex. 5-12 | Same as in Ex. 5-20 | Same as in Ex. 5-12 | <0.5 |
| Ex. 5-32 | Same solvent as used in step (5-3) of Ex. 5-13 | Same as in Ex. 5-20 | Same as in Ex. 5-13 | <0.5 |
| Ex. 5-33 | Same solvent as used in step (5-3) of Ex. 5-14 | Same as in Ex. 5-20 | Same as in Ex. 5-14 | <0.5 |
| Ex. 5-34 | Same solvent as used in step (5-3) of Ex. 5-15 | Same as in Ex. 5-20 | Same as in Ex. 5-15 | <0.5 |
| Ex. 5-35 | Same solvent as used in step (5-3) of Ex. 5-16 | Same as in Ex. 5-20 | Same as in Ex. 5-16 | <0.5 |
| Ex. 5-36 | Same solvent as used in step (5-3) of Ex. 5-17 | Same as in Ex. 5-20 | Same as in Ex. 5-17 | <0.5 |
| Ex. 5-37 | Same solvent as used in step (5-3) of Ex. 5-18 | Same as in Ex. 5-20 | Same as in Ex. 5-18 | <0.5 |
| Ex. 5-38 | Same solvent as used in step (5-3) of Ex. 5-19 | Same as in Ex. 5-20 | Same as in Ex. 5-19 | 9 |

As is seen from the above, the results of Examples 3-18 to 3-34 and Comparative Examples 3-8 to 3-14 were similar to those of Examples 3-1 to 3-17 and Comparative Examples 3-1 to 3-7 even when the means of replacing the water-based cleaning liquid with the supercritical fluid in the step (3-2) was different from that of Example 3-1.

The results of Examples 4-20 to 4-38 and Comparative Examples 4-8 to 4-14 were similar to those of Examples 4-1 to 4-19 and Comparative Examples 4-1 to 4-7, as is seen from the above, even when the means of replacing the water-soluble organic solvent with the supercritical fluid in the step (4-3) was different from that of Example 4-1.

Furthermore, the results of Examples 5-20 to 5-38 and Comparative Examples 5-8 to 5-14 were similar to those of Examples 5-1 to 5-19 and Comparative Examples 5-1 to 5-7, as is seen from the above, even when the means of replacing the water-soluble organic solvent with the supercritical fluid in the step (5-3) was different from that of Example 5-1.

1. A processing method of a semiconductor substrate, comprising:
cleaning a surface of the semiconductor substrate with a water-based cleaning liquid; and
drying the semiconductor substrate by replacing the cleaning liquid adhered to the surface of the semiconductor substrate with a supercritical fluid,
wherein the supercritical fluid is of a fluoroalcohol-containing solvent which contains a C₂-C₆ fluoroalcohol and whose Fe, Ni, Cr, Al, Zn, Cu, Mg, Li, K, Na and Ca contents are each 500 mass ppb or less.

2.-8. (canceled)

9. The processing method of the semiconductor substrate according to claim 1, wherein the processing method involves the following steps:
(2-1) supplying the water-based cleaning liquid to the surface of the semiconductor substrate;
(2-2) supplying the fluoroalcohol-containing solvent to the surface of the semiconductor substrate to which the water-based cleaning liquid has been attached;
(2-3) moving the semiconductor substrate to which the fluoroalcohol-containing solvent has been attached into a chamber, and then, replacing the fluoroalcohol-containing solvent attached to the semiconductor substrate with the supercritical fluid of the fluoroalcohol-containing solvent, wherein the supercritical fluid has been separately obtained by controlling temperature and pressure of the fluoroalcohol-containing solvent to be higher than or equal to a critical point of the fluoroalcohol-containing solvent;
(2-4) changing the supercritical fluid to a gas by lowering the pressure inside the chamber; and
(2-5) taking the semiconductor substrate out of the chamber.

10. The processing method of the semiconductor substrate according to claim 9, wherein, in the step (2-2), the fluoroalcohol-containing solvent is supplied to the surface of the semiconductor substrate such that the water-based cleaning liquid attached to the semiconductor substrate is replaced with the fluoroalcohol-containing solvent.

11. The processing method of the semiconductor substrate according to claim 9, wherein the fluoroalcohol-containing solvent consists of the C₂-C₆ fluoroalcohol.

12. The processing method of the semiconductor substrate according to claim 9, wherein the C₂-C₆ fluoroalcohol contained in the fluoroalcohol-containing solvent has a purity of 99.5% or higher.

13. The processing method of the semiconductor substrate according to claim 9, wherein the C₂-C₆ fluoroalcohol contained in the fluoroalcohol-containing solvent is at least one selected from the group consisting of CH₂CHCH₂C(CF₃)₂OH, CHF₂CF₂CH₂OH, (CF₃)₃COH, CH₃(CF₃)₂COH, CF₃CH(OH)CF₃ and CF₃CH₂OH.

14. The processing method of the semiconductor substrate according to claim 9, wherein the water-based cleaning liquid has a water content of 80 mass % or more.

15. The processing method of the semiconductor substrate according to claim 9, wherein the water-based cleaning liquid is water.

16. The processing method of the semiconductor substrate according to claim 1, wherein the processing method involves the following steps:
(3-1) supplying the water-based cleaning liquid to the surface of the semiconductor substrate;
(3-2) moving the semiconductor substrate to which the water-based cleaning liquid has been attached into a chamber, and then, replacing the water-based cleaning liquid attached to the semiconductor substrate with the supercritical fluid of the fluoroalcohol-containing solvent, wherein the supercritical fluid has been obtained by controlling temperature and pressure of the fluoroalcohol-containing solvent to be higher than or equal to a critical point of the fluoroalcohol-containing solvent;
(3-3) changing the supercritical fluid to a gas by lowering the pressure inside the chamber; and
(3-4) taking the semiconductor substrate out of the chamber.

17. The processing method of the semiconductor substrate according to claim 16, wherein the fluoroalcohol-containing solvent consists of the C₂-C₆ fluoroalcohol.

18. The processing method of the semiconductor substrate according to claim 16, wherein the C₂-C₆ fluoroalcohol contained in the fluoroalcohol-containing solvent has a purity of 99.5% or higher.

19. The processing method of the semiconductor substrate according to claim 16, wherein the C₂-C₆ fluoroalcohol contained in the fluoroalcohol-containing solvent is at least one selected from the group consisting of CH₂CHCH₂C(CF₃)₂OH, CHF₂CF₂CH₂OH, (CF₃)₃COH, CH₃(CF₃)₂COH, CF₃CH(OH)CF₃ and CF₃CH₂OH.

20. The processing method of the semiconductor substrate according to claim 16, wherein the water-based cleaning liquid has a water content of 80 mass % or more.

21. The processing method of the semiconductor substrate according to claim 16, wherein the water-based cleaning liquid is water.

22.-39. (canceled)

40. A solvent for use in the processing method according to claim 1, comprising a C₂-C₆ fluoroalcohol, each of Fe, Ni, Cr, Al, Zn, Cu, Mg, Li, K, Na and Ca contents of the solvent being 500 mass ppb or less.

41. The fluoroalcohol-containing solvent according to claim 40, wherein the solvent consists of the C₂-C₆ fluoroalcohol.

42. The fluoroalcohol-containing solvent according to claim 40, wherein the C₂-C₆ fluoroalcohol has a purity of 99.5% or higher.

43. The fluoroalcohol-containing solvent according to claim 40, wherein the C₂-C₆ fluoroalcohol is at least one selected from the group consisting of CH₂CHCH₂C(CF₃)₂OH, CHF₂CF₂CH₂OH, (CF₃)₃COH, CH₃(CF₃)₂COH, CF₃CH(OH)CF₃ and CF₃CH₂OH.
